(19) United States
(12) Patent Application Publication
(10) Pub. No.: US 2024/0063097 A1
(43) Pub. Date: Feb. 22, 2024

(54) SEMICONDUCTOR DEVICE

(71) Applicant: ROHM CO., LTD., Ukyo-ku (JP)

(72) Inventor: Katsutoki SHIRAI, Ukyo-ku (JP)

(21) Appl. No.: 18/360,470

(22) Filed: Jul. 27, 2023

(30) Foreign Application Priority Data
Aug. 19, 2022 (JP) 2022-131066

(51) Int. Cl. H01L 23/495; H01L 23/00

(52) U.S. Cl. CPC H01L 23/49562; H01L 23/49503; H01L 24/48; H01L 2924/13064; H01L 2224/48247; H01L 2924/1033

(57) ABSTRACT

A semiconductor device includes: a first lead having a die pad; a second lead arranged to be spaced apart from the first lead; a first semiconductor element mounted on the die pad; and a plurality of wires electrically connected to the first semiconductor element and the second lead, wherein the die pad and the second lead are arranged side by side in a first direction perpendicular to a thickness direction, and wherein all of the plurality of wires are inclined with respect to the first direction when viewed in the thickness direction.

### CROSS-REFERENCE TO RELATED APPLICATION

This application is based upon and claims the benefit of priority from Japanese Patent Application No. 2022-131066, filed on Aug. 19, 2022, the entire contents of which are incorporated herein by reference.

### TECHNICAL FIELD

The present disclosure relates to a semiconductor device.

### BACKGROUND

Various configurations have been proposed for semiconductor devices that include semiconductor elements. A DFN (Dual Flatpack No-leaded) type semiconductor device is known. An example of the DFN type semiconductor device includes a semiconductor element, a first lead, a third lead, a plurality of bonding wires, and a sealing resin. The semiconductor element is mounted on a main surface of a mounting portion of the first lead, and a large number of third electrodes (drain electrodes) are connected to the third lead by the bonding wires, respectively.

### BRIEF DESCRIPTION OF DRAWINGS

The accompanying drawings, which are incorporated in and constitute a part of the specification, illustrate embodiments of the present disclosure.

FIG. 1 is a perspective view showing a semiconductor device according to a first embodiment of the present disclosure.

FIG. 2 is a plan view showing the semiconductor device of FIG. 1, and is a view transparent to a sealing resin.

FIG. 3 is a bottom view showing the semiconductor device of FIG. 1.

FIG. 4 is a cross-sectional view taken along line IV-IV in FIG. 2.

FIG. 5 is a cross-sectional view taken along line V-V in FIG. 2.

FIG. 6 is a cross-sectional view taken along line VI-VI in FIG. 2.

FIG. 7 is a partially-enlarged view of FIG. 2.

FIG. 8 is a partially-enlarged view of FIG. 2.

FIG. 9 is a plan view showing a die pad.

FIG. 10 is a plan view showing a die pad of a semiconductor device according to a first modification of the first embodiment.

FIG. 11 is a plan view showing a die pad of a semiconductor device according to a second modification of the first embodiment.

FIG. 12 is a plan view showing a die pad of a semiconductor device according to a third modification of the first embodiment.

FIG. 13 is a plan view showing a die pad of a semiconductor device according to a fourth modification of the first embodiment.

FIG. 14 is a plan view showing a die pad of a semiconductor device according to a fifth modification of the first embodiment.

FIG. 15 is a plan view showing a die pad of a semiconductor device according to a sixth modification of the first embodiment.

FIG. 16 is a plan view showing a die pad of a semiconductor device according to a seventh modification of the first embodiment.

FIG. 17 is a plan view showing a die pad of a semiconductor device according to an eighth modification of the first embodiment.

FIG. 18 is a plan view showing a die pad of a semiconductor device according to a ninth modification of the first embodiment.

FIG. 19 is a cross-sectional view showing a semiconductor device according to a second embodiment.

FIG. 20 is a plan view showing a semiconductor device according to a third embodiment, and is a view transparent to a sealing resin.

FIG. 21 is a plan view showing a semiconductor device according to a first modification of the third embodiment, and is a view transparent to a sealing resin.

FIG. 22 is a plan view showing a semiconductor device according to a fourth embodiment, and is a view transparent to a sealing resin.

FIG. 23 is a plan view showing a semiconductor device according to a fifth embodiment, and is a view transparent to a sealing resin.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be specifically described with reference to the accompanying drawings.

In the present disclosure, the phrases “a certain thing A is formed in another certain thing B” and “a certain thing A is formed on another certain thing B” include, unless otherwise specified, “a certain thing A is directly formed in another certain thing B” and “a certain thing A is formed in another certain thing B with other thing interposed between the certain thing A and the another certain thing B.” Similarly, the phrases “a certain thing A is arranged in another certain thing B” and “a certain thing A is arranged on another certain thing B” include, unless otherwise specified, “a certain thing A is directly arranged in another certain thing B” and “a certain thing A is arranged in another certain thing B with other thing interposed between the certain thing A and the another certain thing B.” Similarly, the phrase “a certain thing A is located on another certain thing B” includes, unless otherwise specified, “a certain thing A is located on another certain thing B and the certain thing A is in contact with the another certain thing B” and “a certain thing A is located on another certain thing B with other thing interposed between the certain thing A and the another certain thing B.” In addition, the phrase “a certain thing A overlaps with another certain thing B when viewed in a certain direction” includes, unless otherwise specified, “a certain thing A overlaps entirely with another certain thing B” and “a certain thing A overlaps partially with another certain thing B.”

### First Embodiment

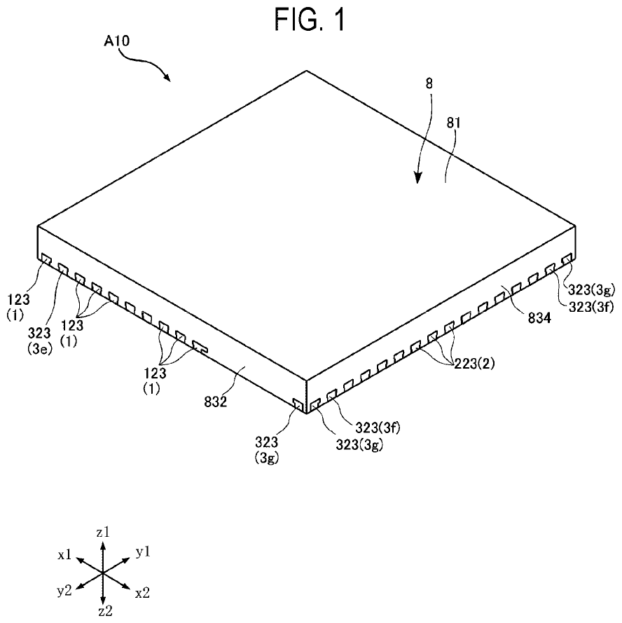

FIGS. 1 to 9 show an example of a semiconductor device according to the present disclosure. A semiconductor device A10 of the present embodiment includes a lead 1, a lead 2, a plurality of leads 3, semiconductor elements 61 and 62, a plurality of wires 7, and a sealing resin 8. The semiconductor device A10 is used in, for example, a gate driver circuit of an inverter device of an electric vehicle, a hybrid vehicle, or the like. The semiconductor device A10 amplifies a control signal input from the outside and outputs it to a switching element (not shown). The application and function of the semiconductor device A10 are not limited. The package format of the semiconductor device A10 is a QFN type. However, the package format of the semiconductor device A10 is not limited to the QFN type.

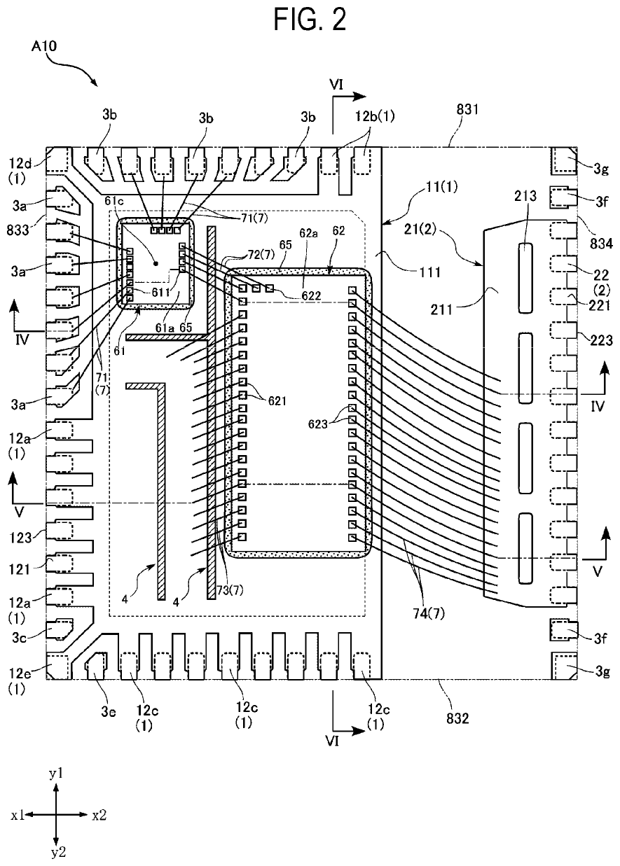

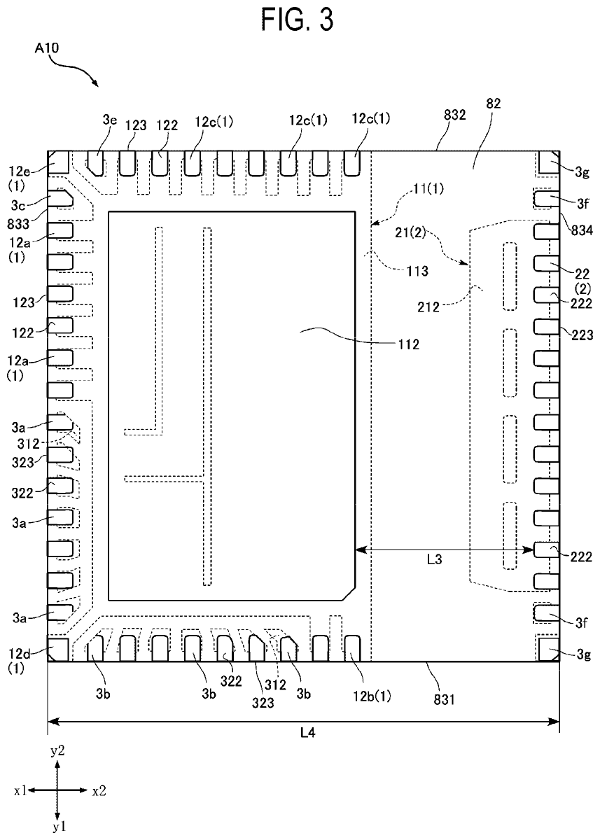

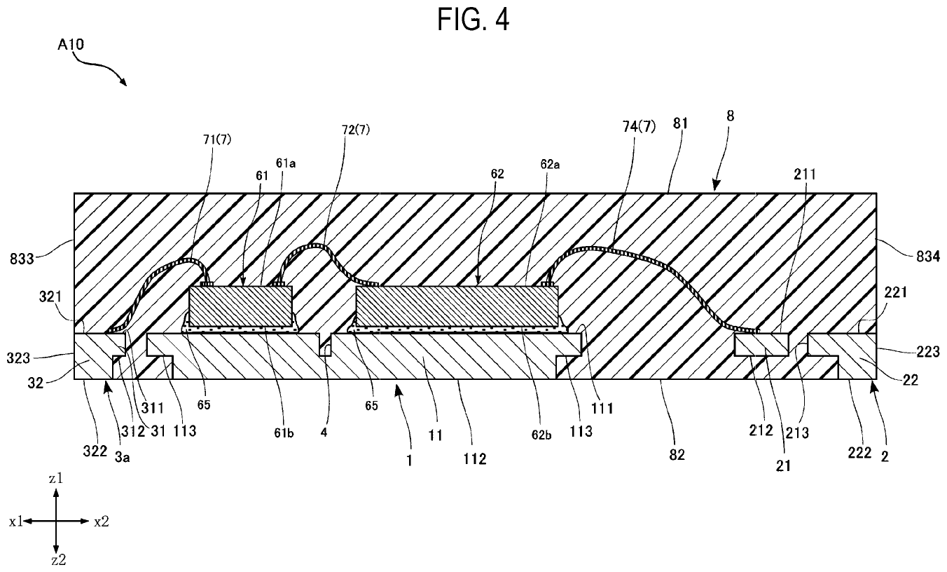

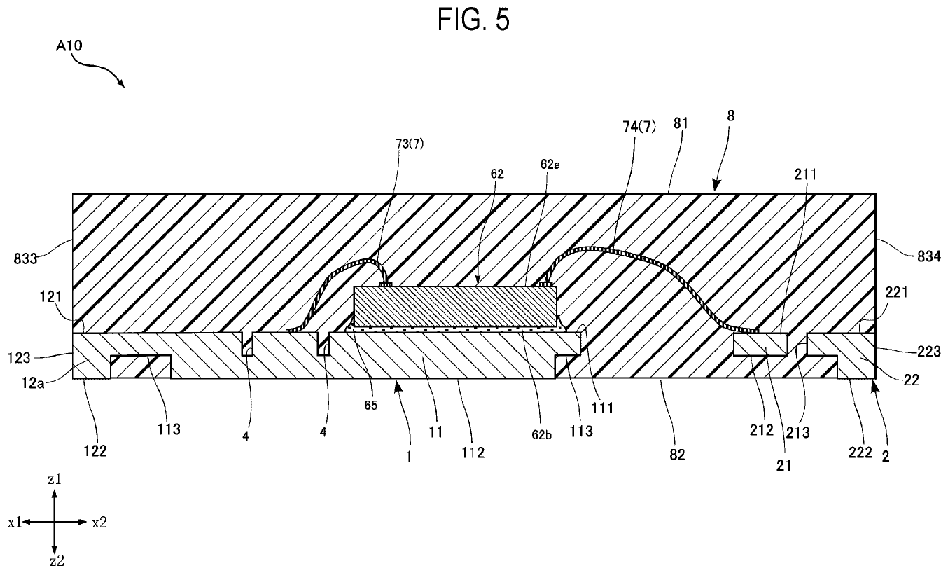

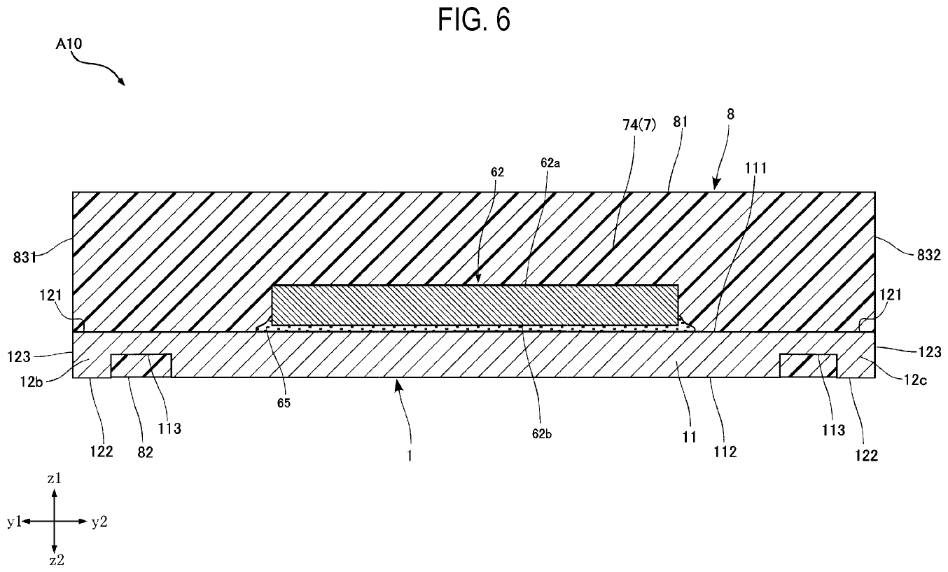

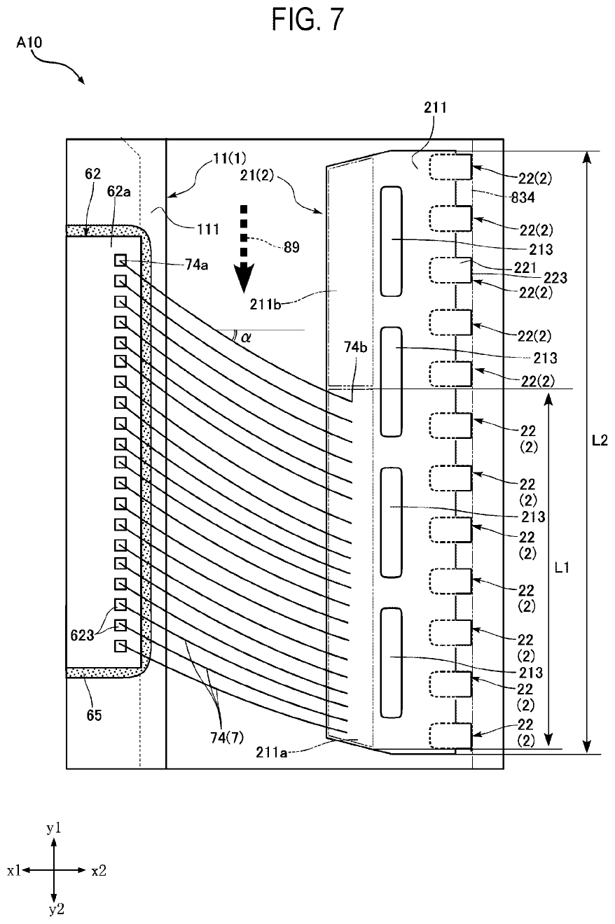

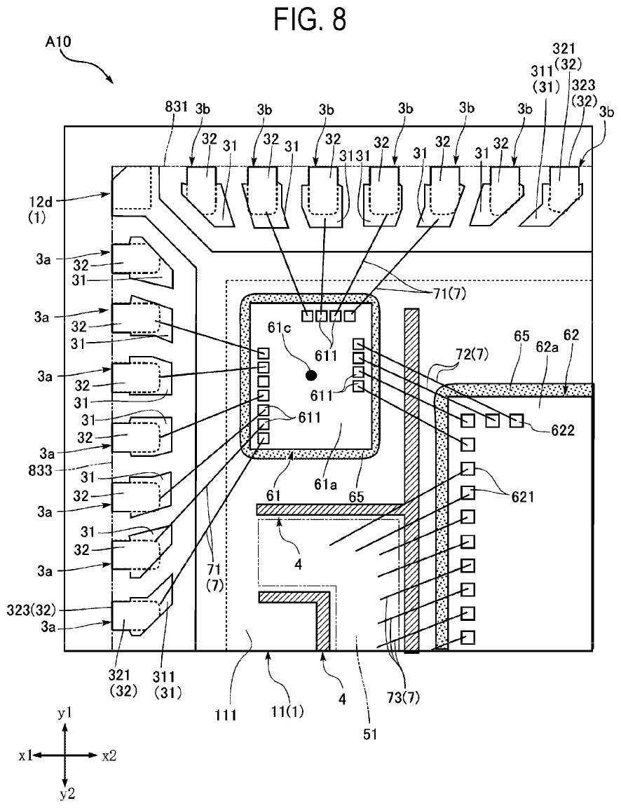

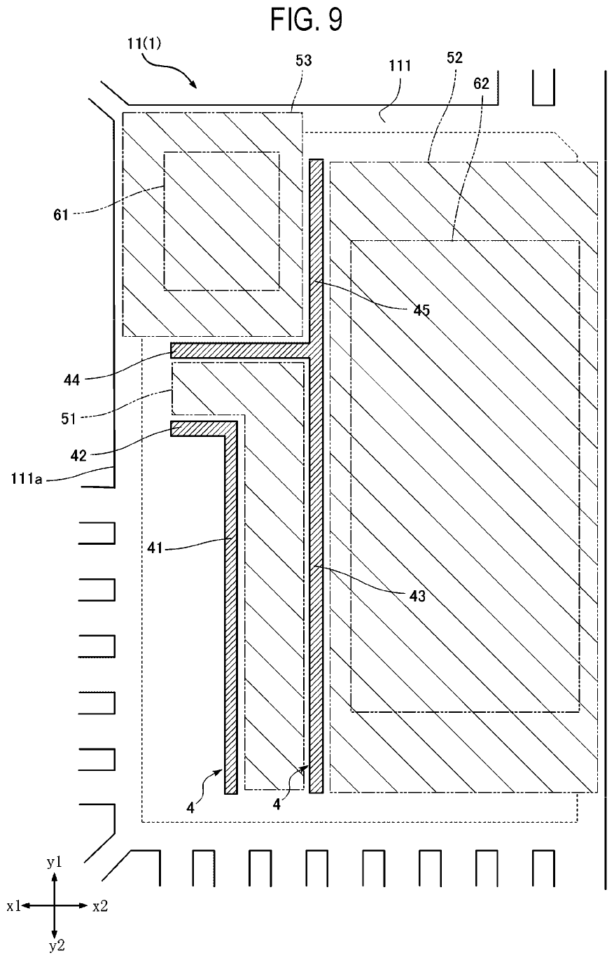

FIG. 1 is a perspective view showing the semiconductor device A10. FIG. 2 is a plan view showing the semiconductor device A10. In FIG. 2, for the sake of convenience of understanding, the sealing resin 8 is transparent and an outer shape of the sealing resin 8 is indicated by an imaginary line (two-dot chain line). FIG. 3 is a bottom view showing the semiconductor device A10. FIG. 4 is a cross-sectional view taken along line IV-IV in FIG. 2. FIG. 5 is a cross-sectional view taken along line V-V in FIG. 2. FIG. 6 is a cross-sectional view taken along line VI-VI of FIG. 2. FIG. 7 is a partially-enlarged view of FIG. 2. FIG. 8 is a partially-enlarged view of FIG. 2. FIG. 9 is a plan view showing a die pad 11 (to be described later) of the lead 1.

The semiconductor device A10 has a rectangular shape when viewed in a thickness direction thereof (plan view). For the sake of convenience of explanation, the thickness direction (plan view direction) of the semiconductor device A10 is referred to as a thickness direction z, a direction (horizontal direction in FIGS. 2 and 3) along one side of the semiconductor device A10 perpendicular to the thickness direction z is referred to as a first direction x, and a direction (vertical direction in FIGS. 2 and 3) perpendicular to the thickness direction z and the first direction x is referred to as a second direction y. In addition, one side (upper side in FIGS. 4 to 6) in the thickness direction z is referred to as a first side z1, and the other side (lower side in FIGS. 4 to 6) is referred to as a second side z2. One side (left-hand side in FIGS. 1 and 2) in the first direction x is referred to as a first side x1, and the other side (right-hand side in FIGS. 1 and 2) is referred to as a second side x2. One side (upper side in FIG. 2) in the second direction y is referred to as a first side y1, and the other side (lower side in FIG. 2) is referred to as a second side y2. The shape and dimensions of the semiconductor device A10 are not limited.

The lead 1, the lead 2, and the plurality of leads 3 (hereinafter also collectively referred to as “leads 1 to 3”) are members forming a conduction path between the semiconductor elements 61 and 62 and a wiring board on which the semiconductor device A10 is mounted. Some of the plurality of leads 3 include those that are not electrically connected to the semiconductor elements 61 and 62. The leads 1 to 3 are formed, for example, by etching or punching a metal plate. The leads 1 to 3 are made of metal and, in some embodiments, are made of one of Cu and Ni or an alloy thereof, a 42 alloy, or the like. In the present embodiment, a case where the leads 1 to 3 are made of Cu will be described as an example. Thicknesses of the leads 1 to 3 are, for example, 0.08 mm to 0.3 mm and, in the present embodiment, are about 0.2 mm.

As shown in FIG. 2, the lead 1 is arranged closer to the first side x1 in the first direction x of the semiconductor device A10 and spreads over the entirety in the second direction y. The lead 2 is spaced apart from the lead 1 and is arranged closer to the second side x2 in the first direction x of the semiconductor device A10. Each lead 3 is spaced apart from the lead 1 and the lead 2, and is spaced apart from one another and arranged at one of both ends in the first direction x and both ends in the second direction y of the semiconductor device A10. The lead 1 is larger than the lead 2, and each lead 3 is larger than the lead 2 as viewed in the thickness direction z.

The lead 1 supports the semiconductor elements 61 and 62 and has a die pad 11 and a plurality of terminals 12.

The semiconductor element 61 and the semiconductor element 62 are mounted on the die pad 11. The die pad 11 is located closer to the first side x1 in the first direction x of the semiconductor device A10 and at the center in the second direction y, and has a substantially rectangular shape when viewed in the thickness direction z. The die pad 11 has a main surface 111, a back surface 112, and a back side recess 113. The main surface 111 and the back surface 112 face opposite sides to each other in the thickness direction z. The main surface 111 faces the first side z1 in the thickness direction z. The main surface 111 is a surface on which the semiconductor elements 61 and 62 are mounted. The main surface 111 has an edge 111a, as shown in FIG. 9. The edge 111a is an edge disposed on the first side x1 of the main surface 111 in the first direction x and extending in the second direction y. The back surface 112 faces the second side z2 in the thickness direction z. The back surface 112 is exposed from the sealing resin 8 and serves as a back surface terminal.

The back side recess 113 is a portion of the die pad 11 and is recessed from the back surface 112 toward the first side z1 in the thickness direction z. A thickness (a dimension in the thickness direction z) of the portion of the die pad 11 where the back side recess 113 is located is about half a thickness of a portion where the back surface 112 is located. The back side recess 113 is formed, for example, by half-etching from the second side z2 in the thickness direction z. As shown in FIG. 3, the back side recess 113 is arranged around the back surface 112. The back side recess 113 is not exposed from the sealing resin 8 and is covered with the sealing resin 8. This prevents the lead 1 from peeling off from the sealing resin 8 toward the second side z2 in the thickness direction z. In addition, the shape of the die pad 11 is not limited. For example, the die pad 11 may not include the back side recess 113.

The die pad 11 has openings 4. In FIGS. 2, 8, and 9, the openings 4 are hatched relatively finely for the sake of convenience of understanding. The openings 4 are openings having an open end on the main surface 111. In the present embodiment, the openings 4 are recesses recessed from the main surface 111 toward the second side z2 in the thickness direction z. A depth (a dimension in the thickness direction z) of the openings 4 is about half a thickness (a distance between the main surface 111 and the back surface 112 in the thickness direction z) of the die pad 11. The openings 4 are formed, for example, by half-etching from the first side z1 in the thickness direction z. The openings 4 include openings 41 to 45, as shown in FIG. 9.

The opening 41 is located between the semiconductor element 62 and the edge 111a indicated by an imaginary line (two-dot chain line) in FIG. 9 in the first direction x and extends in the second direction y. In the present embodiment, when viewed in the thickness direction z, both ends of the opening 41 in the second direction y are located inside an outer edge of the main surface 111. The opening 42 is connected to an end of the opening 41 on the first side y1 in the second direction y and extends to the first side x1 in the first direction x. That is, the opening 42 is located on the first side x1 of the opening 41 in the first direction x. In the present embodiment, when viewed in the thickness direction z, both ends of the opening 42 in the first direction x are located inside the outer edge of the main surface 111. The semiconductor element 61 indicated by an imaginary line (two-dot chain line) in FIG. 9 is arranged on the first side y1 of the opening 42 in the second direction y. A portion of the openings 4 formed by the opening 41 and the opening 42 has an L shape when viewed in the thickness direction z.

The opening 43 is located between the semiconductor element 62 and the opening 41 in the first direction x, and extends in the second direction y. In the present embodiment, when viewed in the thickness direction z, both ends of the opening 43 in the second direction y are located inside the outer edge of the main surface 111. The opening 44 is connected to an end of the opening 43 on the first side y1 in the second direction y and extends to the first side x1 in the first direction x. That is, the opening 44 is located on the first side x1 of the opening 43 in the first direction x. In addition, the opening 44 is located between the semiconductor element 61 and the opening 42 in the second direction y. In the present embodiment, when viewed in the thickness direction z, both ends of the opening 44 in the first direction x are located inside the outer edge of the main surface 111. The opening 45 is connected to an end of the opening 43 on the first side y1 in the second direction y and extends to the first side y1 in the second direction y. That is, the opening 45 is located on the first side y1 of the opening 43 in the second direction y. In the present embodiment, when viewed in the thickness direction z, both ends of the opening 45 in the second direction y are located inside the outer edge of the main surface 111. A portion of the openings 4 formed by the opening 43, the opening 44, and the opening 45 has a T shape when viewed in the thickness direction z.

The main surface 111 of the die pad 11 includes a first region 51, a second region 52, and a third region 53, as shown in FIG. 9. In FIG. 9, the first region 51, the second region 52, and the third region 53 are indicated by imaginary lines (two-dot chain lines), and are hatched relatively roughly. The first region 51 is a region sandwiched between the openings 41 and 42 and the openings 43 and 44. The first region 51 is located on the first side x1 of the semiconductor element 62 in the first direction x and, as shown in FIG. 2, is a region to which the wires 7 (wires 73 to be described later) is bonded. The first region 51 may be subjected to a plating treatment. A plated layer formed by the plating treatment is made of metal including, for example, Ag. The plated layer increases a bonding strength of the wires 73 and protects the lead 1 from an impact during wire bonding of the wires 73. The second region 52 is a region on the second side x2 of the openings 43 and 45 in the first direction x. The second region 52 is a region on which the semiconductor element 62 is mounted, as shown in FIG. 2. The third region 53 is a region on the first side x1 of the opening 45 in the first direction x and on the first side y1 of the opening 44 in the second direction y. The third region 53 is located on the first side x1 from the center in the first direction x of the main surface 111 of the die pad 11, and is located on the first side y1 from the center in the second direction y. The third region 53 is a region on which the semiconductor element 61 is mounted, as shown in FIG. 2.

Conversely, the first region 51, the second region 52, and the third region 53 are regions partitioned by the openings 4. The opening 43 partitions the first region 51 and the second region 52. The opening 44 partitions the first region 51 and the third region 53. The opening 45 partitions the second region 52 and the third region 53. The shape and arrangement of the openings 4 are not limited to those described above, and the shape and arrangement of the first region 51, the second region 52, and the third region 53 are not limited to those described above.

The plurality of terminals 12 is bonded to the wiring board when the semiconductor device A10 is mounted on the wiring board. Each terminal 12 is connected to the die pad 11 and has a substantially rectangular shape when viewed in the thickness direction z. The plurality of terminals 12 includes six terminals 12a, two terminals 12b, eight terminals 12c, and terminals 12d and 12e. The six terminals 12a are connected to the first side x1 of the die pad 11 in the first direction x, and are arranged closer to the second side y2 in the second direction y along the second direction y. The six terminals 12a overlap the openings 4 (the opening 41) when viewed in the first direction x. The two terminals 12b are connected to the first side y1 of the die pad 11 in the second direction y, and are arranged closer to the second side x2 in the first direction x along the second direction y. The eight terminals 12c are connected to the second side y2 of the die pad 11 in the second direction y and are arranged along the first direction x. The terminal 12d is connected to a corner of the die pad 11, which is on the first side x1 in the first direction x and the first side y1 in the second direction y. The terminal 12e is connected to a corner of the die pad 11, which is on the first side x1 in the first direction x and the second side y2 in the second direction y.

Each terminal 12 has a main surface 121, a back surface 122, and an end surface 123. The main surface 121 and the back surface 122 face opposite sides to each other in the thickness direction z. The main surface 121 faces the first side z1 in the thickness direction z. The main surface 121 and the main surface 111 of the die pad 11 are flush with each other. The back surface 122 faces the second side z2 in the thickness direction z. The back surface 122 and the back surface 112 of the die pad 11 are spaced apart from each other as shown in FIG. 3, and have the same position in the thickness direction z. The end surface 123 is a surface perpendicular to the main surface 121 and the back surface 122 and connected to the main surface 121 and the back surface 122. Each of the terminal 12d and the terminal 12e has two end surfaces 123. The end surface 123 is formed by singulation in a cutting step in a manufacturing process. The end surface 123 and the back surface 122 are exposed from the sealing resin 8 and connected to each other to serve as terminals (see FIG. 5). The shape, arrangement position, and number of terminals 12 are not limited.

The lead 2 is spaced apart from the lead 1 and arranged on the second side x2 in the first direction x. The die pad 11 of the lead 1 and the lead 2 are arranged side by side in the first direction x. The lead 2 is conductively connected to the semiconductor element 62 by the plurality of wires 7 (a plurality of wires 74 to be described later). The lead 2 has a pad 21 and a plurality of terminals 22.

The plurality of wires 74 is bonded to the pad 21. The pad 21 has a main surface 211, a back surface 212, and through-holes 213. The main surface 211 and the back surface 212 face opposite sides to each other in the thickness direction z. The main surface 211 faces the first side z1 in the thickness direction z. The main surface 211 is a surface to which the plurality of wires 74 is bonded. The main surface 211 includes a bonding region 211a and a non-bonding region 211b, as shown in FIG. 7. In FIG. 7, the bonding region 211a and the non-bonding region 211b are indicated by imaginary lines (two-dot chain lines). The bonding region 211a is a region to which the plurality of wires 74 is bonded, and is arranged closer to the second side y2 in the second direction y on the main surface 211. The non-bonding region 211b is a region where the plurality of wires 74 is not bonded, and is arranged on the first side y1 with respect to the bonding region 211a in the second direction y. A dimension L1 of the bonding region 211a in the second direction y is 40% or more and 60% or less of a dimension L2 of the lead 2 in the second direction y. The bonding region 211a may be subjected to a plating treatment. A plated layer formed by the plating treatment is made of metal including, for example, Ag. The plated layer increases a bonding strength of the wires 74 and protects the lead 2 from an impact during wire bonding of the wires 74. The back surface 212 faces the second side z2 in the thickness direction z. The back surface 212 is covered with the sealing resin 8. A thickness (a dimension in the thickness direction z) of the pad 21 is about half a thickness of the die pad 11 and about the same as the thickness of the portion of the die pad 11 where the back side recess 113 is located. The pad 21 is formed, for example, by half-etching from the second side z2 in the thickness direction z.

The through-holes 213 are holes penetrating through the pad 21 in the thickness direction z. The through-holes 213 facilitate filling the back surface 212 of the pad 21 with the material of the sealing resin 8 in a step of forming the sealing resin 8 in the manufacturing process of the semiconductor device A10. In the present embodiment, the pad 21 has four substantially rectangular through-holes 213, which are elongated in the second direction y and arranged in the second direction y. The shape, number, and arrangement of the through-holes 213 are not limited. In addition, the pad 21 may not have the through-holes 213.

The plurality of terminals 22 is bonded to the wiring board when the semiconductor device A10 is mounted on the wiring board. Each terminal 22 is connected to the second side x2 of the pad 21 in the first direction x and has a substantially rectangular shape when viewed in the thickness direction z. In the present embodiment, twelve terminals 22 are arranged at equal intervals along the second direction y.

Each terminal 22 has a main surface 221, a back surface 222, and an end surface 223. The main surface 221 and the back surface 222 face opposite to each other in the thickness direction z. The main surface 221 faces the first side z1 in the thickness direction z. The main surface 221 and the main surface 211 of the pad 21 are flush with each other. The back surface 222 faces the second side z2 in the thickness direction z. In the present embodiment, as shown in FIG. 3, a distance L3 between the back surface 222 of the terminal 22 of the lead 2 and the back surface 112 of the die pad 11 is sufficiently large, for example, 30% or more and 40% or less of a dimension L4 of the semiconductor device A10 in the first direction x. In addition, the distance between the back surface 222 and the back surface 112 is not limited thereto. The end surface 223 is a surface perpendicular to the main surface 221 and the back surface 222, and connected to the main surface 221 and the back surface 222. The end surface 223 is formed by singulation in the cutting step in the manufacturing process. The end surface 223 and the back surface 222 are exposed from the sealing resin 8 and connected to each other to serve as terminals (see FIGS. 4 and 5). The shape, arrangement position, and number of terminals 22 are not limited.

The plurality of leads 3 constitutes conduction paths between the semiconductor elements 61 and 62 and the wiring board on which the semiconductor device A10 is mounted. The plurality of leads 3 also includes so-called dummy leads that are not electrically connected to the semiconductor elements 61 and 62. Each lead 3 has a pad 31 and a terminal 32.

The pad 31 is a portion to which the wire 7 (a wire 71 to be described later) is bonded. In addition, the pad 31 may or may not have the wire 71 bonded thereto. The pad 31 has a main surface 311 and a back surface 312. The main surface 311 and the back surface 312 face opposite sides to each other in the thickness direction z. The main surface 311 faces the first side z1 in the thickness direction z. The main surface 311 is a surface to which the wire 71 is bonded. The main surface 311 may be subjected to a plating treatment. A plated layer formed by the plating treatment is made of metal including, for example, Ag. The plated layer increases a bonding strength of the wire 71 and protects the lead 3 from an impact during wire bonding of the wire 71. The plated layer may be formed only on the lead 3 to which the wire 71 is bonded. The back surface 312 faces the second side z2 in the thickness direction z. The back surface 312 is covered with the sealing resin 8. A thickness (a dimension in the thickness direction z) of the pad 31 is about half the thickness of the die pad 11 and about the same as the thickness of the portion of the die pad 11 where the back side recess 113 is located. The pad 31 is formed, for example, by half-etching from the second side z2 in the thickness direction z.

The terminal 32 is bonded to the wiring board when the semiconductor device A10 is mounted on the wiring board. The terminal 32 is connected to the pad 31 and has a substantially rectangular shape when viewed in the thickness direction z. The terminal 32 has a main surface 321, a back surface 322, and an end surface 323. The main surface 321 and the back surface 322 face opposite sides to each other in the thickness direction z. The main surface 321 faces the first side z1 in the thickness direction z. The main surface 321 and the main surface 311 of the pad 31 are flush with each other. The wire 71 may be bonded to the main surface 321 of the terminal 32. The back surface 322 faces the second side z2 in the thickness direction z. The end surface 323 is a surface perpendicular to the main surface 321 and the back surface 322, and connected to the main surface 321 and the back surface 322. The end surface 323 is formed by singulation in the cutting step in the manufacturing process. The end surface 323 and the back surface 322 are exposed from the sealing resin 8 and connected to each other to serve as terminals (see FIG. 4). The shape of the terminal 32 is not limited.

As shown in FIG. 2, the plurality of leads 3 includes a plurality of leads 3a, a plurality of leads 3b, a lead 3c, a lead 3e, a pair of leads 3f, and a pair of leads 3g.

In the present embodiment, the plurality of leads 3 includes seven leads 3a. However, the number of leads 3a is not limited. The plurality of leads 3a is arranged at the end of the first side x1 in the first direction x of the semiconductor device A10 and closer to the first side y1 in the second direction y. The plurality of leads 3a is arranged on the first side x1 of the die pad 11 in the first direction x, and along the second direction y between the terminal 12a and the terminal 12d in the second direction y. Further, in the present embodiment, the plurality of leads 3 includes seven leads 3b. However, the number of leads 3b is not limited. The plurality of leads 3b is arranged at the end of the first side y1 in the second direction y of the semiconductor device A10, and closer to the first side x1 in the first direction x. The plurality of leads 3b is arranged on the first side y1 of the die pad 11 in the second direction y, and along the first direction x between the terminal 12b and the terminal 12d in the first direction x. The plurality of leads 3a and the plurality of leads 3b are arranged so as to be electrically connected to the semiconductor element 61 via the wires 71. In the present embodiment, most of the plurality of leads 3a and the plurality of leads 3b are electrically connected to the semiconductor element 61, but some of them are not electrically connected to the semiconductor element 61. In addition, which of the plurality of leads 3a and the plurality of leads 3b are electrically connected to the semiconductor element 61, and to which electrode 611 (to be described later) of the semiconductor element 61 the plurality of leads 3a and the plurality of leads 3b are electrically connected, are not limited. As shown in FIG. 8, each pad 31 of the plurality of leads 3a and the plurality of leads 3b extends toward an element center 61c, which is the center of the semiconductor element 61, when viewed in the thickness direction z.

In addition, in the present embodiment, the plurality of leads 3 includes one lead 3c and one lead 3e. However, the number of leads 3c and the number of leads 3e are not limited. The lead 3c is arranged on the first side x1 of the die pad 11 in the first direction x and between the terminal 12a and the terminal 12e in the second direction y. The lead 3e is arranged on the second side y2 of the die pad 11 in the second direction y and between the terminal 12c and the terminal 12e in the first direction x. The leads 3c and 3e are so-called dummy leads.

In addition, in the present embodiment, the plurality of leads 3 includes the pair of leads 3f and the pair of leads 3g. The pair of leads 3g are arranged on the first side y1 and the second side y2 of the lead 2 in the second direction y, respectively. One lead 3g is arranged at a corner of the semiconductor device A10, which is on the second side x2 in the first direction x and the first side y1 in the second direction y, and the other lead 3g is arranged at a corner of the semiconductor device A10, which is on the second side x2 in the first direction x and the second side y2 in the second direction y. In addition, the plurality of leads 3 may not include the leads 3g. The pair of leads 3f are arranged on the first side y1 and the second side y2 of the lead 2 in the second direction y, respectively. The leads 3f are arranged between the lead 2 and the leads 3g, respectively, in the second direction y. The number of leads 3f is not limited. The leads 3f and 3g are so-called dummy leads.

A plated layer containing, for example, Sn may be arranged on surfaces of the leads 1 to 3 exposed from the sealing resin 8. The constituent material of the plated layer is not limited. When the semiconductor device A10 is surface-mounted on the wiring board by solder bonding, the plated layer ensures good adhesion of solder to the exposed surfaces, while preventing corrosion of the exposed surfaces due to the solder bonding. The shape and arrangement of the leads 1 to 3 are not limited to those described above.

The semiconductor element 61 and the semiconductor element 62 are elements that exhibit electrical functions of the semiconductor device A10. The semiconductor element 62 is a switching element. In the present embodiment, the semiconductor element 62 is an HEMT (High Electron Mobility Transistor) using gallium nitride (GaN). A nitride semiconductor other than GaN may be used for the semiconductor element 62. In addition, the semiconductor element 62 may be an IGBT (Insulated Gate Bipolar Transistor), a MOSFET (Metal Oxide Semiconductor Field Effect Transistor), a bipolar transistor, or the like. The semiconductor element 62 includes an element main surface 62a, an element back surface 62b, a plurality of first electrodes 621, a second electrode 622, and a plurality of third electrodes 623.

The element main surface 62a and the element back surface 62b face opposite sides to each other in the thickness direction z. The element main surface 62a is a surface facing the first side z1 in the thickness direction z, and the element back surface 62b is a surface facing the second side z2 in the thickness direction z. The plurality of first electrodes 621, the second electrode 622, and the plurality of third electrodes 623 are arranged on the element main surface 62a. The plurality of first electrodes 621 are source electrodes, and are arranged closer to the first side x1 in the first direction x of the element main surface 62a and side by side along the second direction y. The second electrode 622 is a gate electrode and is arranged closer to the first side y1 in the second direction y of the element main surface 62a. The plurality of third electrodes 623 are drain electrodes, and are arranged closer to the second side x2 in the first direction x of the element main surface 62a and side by side along the second direction y. Other electrodes are also arranged on the element main surface 62a. The layout of the arrangement of the electrodes 621 to 623 is not limited.

As shown in FIGS. 4 to 6, the element back surface 62b of the semiconductor element 62 is bonded to the main surface 111 of the die pad 11 via a bonding member 65. In the present embodiment, the bonding member 65 is, for example, Ag paste. The bonding member 65 may be a conductive bonding material such as solder or a sintered silver bonding material, or may be an insulating bonding member. As shown in FIGS. 2 and 9, the semiconductor element 62 is arranged on the second region 52 of the main surface 111, that is, on the second side x2 of the openings 43 and 44 in the first direction x.

The semiconductor element 61 is a drive element that drives the semiconductor element 62. The semiconductor element 61 generates a drive signal based on a control signal input from the outside and outputs it to the semiconductor element 62. In addition, the semiconductor element 61 controls the drive signal based on a source sense signal or the like input from the semiconductor element 62. The semiconductor element 61 has an element main surface 61a, an element back surface 61b, and a plurality of electrodes 611.

The element main surface 61a and the element back surface 61b face opposite sides to each other in the thickness direction z. The element main surface 61a is a surface facing the first side z1 in the thickness direction z, and the element back surface 61b is a surface facing the second side z2 in the thickness direction z. The plurality of electrodes 611 is arranged on the element main surface 61a. The function and arrangement of each electrode 611 are not limited.

As shown in FIG. 4, the element back surface 61b of the semiconductor element 61 is bonded to the main surface 111 of the die pad 11 via the bonding member 65. As shown in FIGS. 2 and 9, the semiconductor element 61 is arranged on the third region 53 of the main surface 111, that is, on the first side x1 of the opening 45 in the first direction x and on the first side y1 of the opening 44 in the second direction y. The semiconductor element 61 is arranged on the first side x1 with respect to the semiconductor element 62 in the first direction x and on the first side y1 with respect to the semiconductor element 62 in the second direction y. The element center 61c, which is the center of the semiconductor element 61 viewed in the thickness direction z, is located on the first side y1 from the center of the main surface 111 of the die pad 11 in the second direction y, and is located on the first side x1 from the center of the main surface 111 in the first direction x.

As shown in FIG. 2, the plurality of wires 7, together with the leads 1 to 3, form conduction paths for the semiconductor elements 61 and 62 to perform predetermined functions thereof. The constituent material of each wire 7 is, for example, Cu, Au, Ag, Al, an alloy containing any of these, or the like, but is not limited. The plurality of wires 7 includes the plurality of wires 71, 72, 73, and 74.

As shown in FIGS. 2 and 8, the plurality of wires 71 forms conduction paths between the semiconductor element 61 and the plurality of leads 3. Each wire 71 is bonded to be electrically connected to any electrode 611 of the semiconductor element 61 and electrically connected to the main surface 311 of the pad 31 of any of the plurality of leads 3a or the plurality of leads 3b. As a result, the semiconductor element 61 can receive signals from the outside and output signals to the outside via the plurality of leads 3 and wires 71. Since the pads 31 of both of the plurality of leads 3a and the plurality of leads 3b extend toward the element center 61c of the semiconductor element 61 when viewed in the thickness direction z, each wire 71 can be formed so as not to overlap other leads 3 adjacent to the lead 3 to which the wire 71 is bonded, when viewed in the thickness direction z.

As shown in FIGS. 2 and 8, the plurality of wires 72 forms conduction paths between the semiconductor element 61 and the semiconductor element 62. One wire 72 is bonded to be electrically connected to one of the electrodes 611 of the semiconductor element 61 and electrically connected to the second electrode 622 of the semiconductor element 62. The semiconductor element 61 outputs a drive signal to the second electrode 622 via the one wire 72. Each of other wires 72 is bonded to be electrically connected to one of the electrodes 611 of the semiconductor element 61 and electrically connected to any electrode of the semiconductor element 62. A source sense signal is input to the semiconductor element 61 via the wires 72 bonded to the first electrodes 621 (source electrodes) of the semiconductor element 62. In addition, the semiconductor element 61 inputs and outputs signals to and from the semiconductor element 62 via other wires 72.

As shown in FIGS. 2 and 8, the plurality of wires 73 forms conduction paths between the semiconductor element 62 and the die pad 11. Each wire 73 is bonded to be electrically connected to one of the first electrodes 621 of the semiconductor element 62 and electrically connected to the main surface 111 of the die pad 11. As a result, the lead 1 is conductively connected to the first electrodes 621 (source electrodes) of the semiconductor element 62 and functions as a source terminal. In the present embodiment, each wire 73 is bonded to the first region 51 of the main surface 111.

As shown in FIGS. 2 and 7, the plurality of wires 74 forms conduction paths between the semiconductor element 62 and the lead 2. Each wire 74 is bonded to be electrically connected to one of the third electrodes 623 of the semiconductor element 62 and electrically connected to the main surface 211 of the pad 21 of the lead 2. As a result, the lead 2 is conductively connected to the third electrodes 623 (drain electrodes) of the semiconductor element 62 and functions as a drain terminal. In the present embodiment, each wire 74 is bonded to the bonding region 211a of the main surface 211. All of the wires 74 are inclined with respect to the first direction x when viewed in the thickness direction z. As shown in FIG. 7, each wire 74 has a bonding portion 74a bonded to the semiconductor element 62 and a bonding portion 74b bonded to the lead 2. The bonding portion 74a is located on the first side y1 in the second direction y from the bonding portion 74b.

In the step of forming the sealing resin 8 in the manufacturing process of the semiconductor device A10, the material of the sealing resin 8 flows along the second direction y from the first side y1 to the second side y2 in the second direction y, as indicated by a dashed arrow 89 in FIG. 7. Therefore, each wire 74 is curved toward the second side y2 in the second direction y. In addition, since each wire 74 is inclined with respect to the first direction x when viewed in the thickness direction z, a force applied to the wire 74 by the material of the sealing resin 8 is resolved into a component in a direction parallel to the wire 74 and a component in a direction perpendicular to the wire 74. Since the component in the perpendicular direction that affects so-called wire sweep is smaller than that when the wire 74 is parallel to the second direction y, the wire sweep is suppressed. As an inclination angle α of the wire 74 with respect to the first direction x increases, the effect of suppressing the wire sweep may be improved.

The sealing resin 8 covers portions of the leads 1 to 3, the semiconductor elements 61 and 62, and the plurality of wires 7. The sealing resin 8 has electrical insulation. The sealing resin 8 is made of a material containing, for example, black epoxy resin. However, the material of the sealing resin 8 is not limited.

The sealing resin 8 has a resin main surface 81, a resin back surface 82, and four resin side surfaces 83. The resin main surface 81 and the resin back surface 82 face opposite sides to each other in the thickness direction z. The resin main surface 81 is a surface facing the first side z1 in the thickness direction z, and the resin back surface 82 is a surface facing the second side z2 in the thickness direction z.

The four resin side surfaces 83 are surfaces that are perpendicular to the resin main surface 81 and the resin back surface 82, connect the resin main surface 81 and the resin back surface 82, and face outward in the first direction x or the second direction y. Each resin side surface 83 is formed by singulation in the cutting step in the manufacturing process. The four resin side surfaces 83 include a first resin side surface 831, a second resin side surface 832, a third resin side surface 833, and a fourth resin side surface 834. The first resin side surface 831 and the second resin side surface 832 face opposite sides to each other in the second direction y. The first resin side surface 831 is a surface arranged on the first side y1 in the second direction y and facing the first side y1, and the second resin side surface 832 is a surface arranged on the second side y2 in the second direction y and facing the second side y2. The third resin side surface 833 and the fourth resin side surface 834 face opposite sides to each other in the first direction x. The third resin side surface 833 is a surface arranged on the first side x1 in the first direction x and facing the first side x1, and the fourth resin side surface 834 is a surface arranged on the second side x2 in the first direction x and facing the second side x2.

Each end surface 123 of the lead 1 facing the first side x1 in the first direction x and the end surfaces 323 of the lead 3a and 3c are exposed from the third resin side surface 833 and are flush with the third resin side surface 833. Each end surface 123 and each end surface 323 exposed from the third resin side surface 833 are spaced apart from each other and arranged at equal intervals along the second direction y. Each end surface 123 of the lead 1 facing the first side y1 in the second direction y, the end surface 323 of each lead 3b, and the end surface 323 of the lead 3g facing the first side y1 are exposed from the first resin side surface 831 and are flush with the first resin side surface 831. Each end surface 123 and the end surface 323 of each lead 3b exposed from the first resin side surface 831 are spaced apart from each other and arranged at equal intervals along the first direction x. Each end surface 123 of the lead 1 facing the second side y2 in the second direction y, the end surface 323 of the lead 3e, and the end surface 323 of the lead 3g facing the second side y2 are exposed from the second resin side surface 832 and are flush with the resin side surface 832. Each end surface 123 and the end surface 323 of each leads 3e exposed from the second resin side surface 832 are spaced apart from each other and arranged at equal intervals along the first direction x. The end surface 223 of each terminal 22 of the lead 2, the end surface 323 of each lead 3f, and the end surface 323 of each lead 3g facing the second side x2 are exposed from the fourth resin side surface 834 and are flush with the fourth resin side surface 834. Each end surface 223 and each end surface 323 exposed from the fourth resin side surface 834 are spaced apart from each other and arranged at equal intervals along the second direction y. In addition, the back surface 112 of the die pad 11 of the lead 1 and the back surface 122 of each terminal 12, the back surface 222 of each terminal 22 of the lead 2, and the back surface 322 of the terminal 32 of each lead 3 are exposed from the resin back surface 82 and are flush with the resin back surface 82.

Next, operative effects of the semiconductor device A10 will be described.

According to the present embodiment, the semiconductor element 61 is mounted at a position shifted from the center of the main surface 111 of the die pad 11 in the second direction y to the first side y1. In addition, the pad 31 of each lead 3a extends toward the element center 61c when viewed in the thickness direction z. Therefore, the wire 71 bonded to each lead 3a can be formed so as not to overlap other leads 3a adjacent to the lead 3a to which the wire 71 is bonded, when viewed in the thickness direction z. As a result, the semiconductor device A10 can prevent each wire 71 from being in contact with the other adjacent lead 3a. In addition, the semiconductor element 61 is mounted at a position shifted from the center of the main surface 111 of the die pad 11 in the first direction x to the first side x1. In addition, the pad 31 of each lead 3b extends toward the element center 61c when viewed in the thickness direction z. Therefore, the wire 71 bonded to each lead 3b can be formed so as not to overlap other leads 3b adjacent to the lead 3b to which the wire 71 is bonded, when viewed in the thickness direction z. As a result, the semiconductor device A10 can prevent each wire 71 from being in contact with the other adjacent lead 3b.

In addition, according to the present embodiment, each wire 74 is inclined with respect to the first direction x when viewed in the thickness direction z. Therefore, in comparison to a case where the wire 74 is parallel to the first direction x, in the step of forming the sealing resin 8 in the manufacturing process of the semiconductor device A10, a force applied to each wire 74 by the material of the sealing resin 8 flowing in the second direction y is reduced. As a result, the wire sweep of each wire 74 is suppressed, which suppresses contact between the wires 74 due to the wire sweep in the semiconductor device A10. In addition, according to the present embodiment, the bonding portion 74a of each wire 74 is located on the first side y1 in the second direction y from the bonding portion 74b, and has the same inclination direction with respect to the first direction x. Therefore, the wire sweep of each wire 74 is also suppressed, which suppresses contact between the wires 74 due to the wire sweep in the semiconductor device A10.

In addition, according to the present embodiment, the die pad 11 has the openings 4 which are recesses recessed from the main surface 111 toward the second side z2 in the thickness direction z. The openings 4 include the opening 41 located between the first region 51, to which the wires 73 are bonded, and the edge 111a in the first direction x and extending in the second direction y. The opening 41 hinders peeling generated at the edge 111a from progressing to the second side x2 in the first direction x. Since the opening 41 hinders the peeling from progressing to the first region 51, the semiconductor device A10 can suppress peeling of the wires 73 from the die pad 11. In addition, according to the present embodiment, the openings 4 include the opening 42 connected to the end of the opening 41 on the first side y1 in the second direction y and extending to the first side x1 in the first direction x. The opening 42 hinders the peeling generated at the edge 111a from progressing to the first side y1 in the second direction y. Since the opening 42 hinders the peeling from progressing to the first region 51 and the second region 52, the semiconductor device A10 can suppress the peeling of the wires 73 from the die pad 11 and peeling of the semiconductor element 61 from the die pad 11.

In addition, according to the present embodiment, the openings 4 include the opening 43 located in the first direction x between the second region 52 on which the semiconductor element 62 is mounted and the first region 51 to which the wire 73 is bonded, and extending in the second direction y. Even when the molten bonding member 65 flows out when the semiconductor element 62 is bonded to the die pad 11 in the manufacturing process, the opening 43 can suppress the molten bonding member 65 from flowing to the first region 51. Accordingly, it is possible to suppress the bonding member 65 from hindering the bonding of the wires 73. In addition, since the opening 43 hinders peeling of the sealing resin 8 from the die pad 11 from progressing to the first side x1 in the first direction x, it can also contribute to suppressing the peeling of the wires 73 from the die pad 11. In addition, according to the present embodiment, the openings 4 include the opening 44 connected to the end of the opening 43 on the first side y1 in the second direction y and extending to the first side x1 in the first direction x. Even when the molten bonding member 65 flows out when the semiconductor element 61 is bonded to the die pad 11 in the manufacturing process, the opening 44 can suppress the molten bonding member 65 from flowing to the first region 51. Accordingly, it is possible to suppress the bonding member 65 from hindering the bonding of the wire 73. Further, since the opening 44 prevents the peeling of the sealing resin 8 from the die pad 11 from progressing to the second side y2 in the second direction y, it can also contribute to suppressing the peeling of the wire 73 from the die pad 11. In addition, according to the present embodiment, the openings 4 includes the opening 45 connected to the end of the opening 43 on the first side y1 in the second direction y and extending to the first side y1 in the second direction y. The opening 45 suppresses concentration of a stress at a connection point between the opening 43 and the opening 44 and strengthens bonding between the sealing resin 8 and the die pad 11. In addition, the opening 43, the opening 44, and the opening 45 also have a function of partitioning the first region 51, the second region 52, and the third region 53 to clearly indicate positions for mounting the semiconductor element 61 and the semiconductor element 62.

In addition, according to the present embodiment, each end of the openings 4 is located inside the outer edge of the main surface 111 of the die pad 11. Therefore, the strength of the die pad 11 can be increased as compared with a case where each end of the openings 4 extends to the outer edge of the main surface 111. In addition, according to the present embodiment, the openings 4 are recesses recessed from the main surface 111 toward the second side z2 in the thickness direction z. Therefore, the strength of the die pad 11 can be increased as compared with a case where the openings 4 penetrate the die pad 11 in the thickness direction z.

In addition, according to the present embodiment, a distance between the back surface 112 of the die pad 11 and the back surface 222 of the terminal 22 of the lead 2 is sufficiently large. Therefore, electrical connection between the back surface 112 and the back surface 222 due to dielectric breakdown is suppressed. On the other hand, a dimension of the pad 21 of the lead 2 in the first direction x is sufficiently large. As a result, a length of the wires 74 that electrically connect the semiconductor element 62 and the pad 21 can be reduced.

In addition, according to the present embodiment, the semiconductor device A10 includes the leads 3c, 3e, 3f, and 3g, which are dummy leads. Therefore, the semiconductor device A10 has improved mounting reliability as compared with a case where the leads 3c, 3e, 3f, and 3g are not provided. In addition, according to the present embodiment, the lead 1 has the terminals 12a, 12b, and 12c. Therefore, the semiconductor device A10 has improved heat dissipation and improved strength for supporting the die pad 11 as compared with a case where leads spaced apart from the lead 1 are provided instead of the terminals 12a, 12b, and 12c.

In the present embodiment, the case where the openings 4 include all of the openings 41 to 45 has been described, but the present disclosure is not limited thereto. The openings 4 may not include any of the openings 41 to 45. In addition, the die pad 11 may not have the openings 4. In addition, in the present embodiment, the case where each wire 74 is inclined with respect to the first direction x when viewed in the thickness direction z has been described, but the present disclosure is not limited thereto. Each wire 74 may be parallel to the first direction x when viewed in the thickness direction z. In addition, in the present embodiment, the case where both the pad 31 of each lead 3a and the pad 31 of each lead 3b extend toward the element center 61c when viewed in the thickness direction z has been described, but the present disclosure is not limited thereto. The pad 31 of each lead 3a may extend to the second side x2 in the first direction x. In addition, the pad 31 of each lead 3b may extend to the second side y2 in the second direction y. In addition, the package format of the semiconductor device A10, the types and number of the semiconductor elements 61 and 62 to be mounted, and the shape, number, and arrangement of the leads 1 to 3 are not particularly limited.

In addition, in the present embodiment, the case where the bonding region 211a is arranged closer to the second side y2 of the main surface 211 in the second direction y has been described, but the present disclosure is not limited thereto. The bonding region 211a may be arranged closer to the first side y1 of the main surface 211 in the second direction y. In this case, the bonding portion 74a of the wire 74 is located on the second side y2 in the second direction y from the bonding portion 74b.

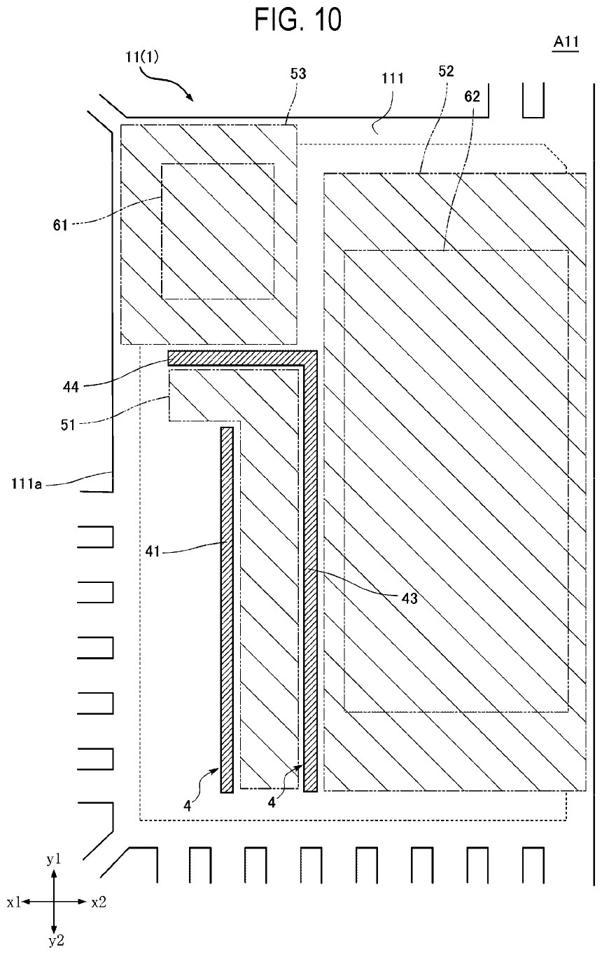

FIGS. 10 to 18 show modifications of the semiconductor device A10 according to the first embodiment. In these figures, the same or similar elements as in the above embodiment are denoted by the same reference numerals as in the above embodiment, and duplicate explanation thereof will be omitted.

### First Modification

FIG. 10 is a view for explaining a semiconductor device All according to a first modification of the first embodiment. FIG. 10 is a plan view showing the die pad 11 of the semiconductor device All, and corresponds to FIG. 9. The semiconductor device All is different from the semiconductor device A10 in the configuration of the openings 4.

The openings 4 of the semiconductor device All according to this modification do not include the opening 42 and the opening 45. Also in this modification, since the openings 4 include the opening 41, the peeling generated at the edge 111a is hindered from progressing to the first region 51, so that the peeling of the wires 73 from the die pad 11 is suppressed. In addition, since the openings 4 include the opening 43 and the opening 44, it is possible to suppress the outflow of the molten bonding member 65 to the first region 51, and it is also possible to contribute to suppressing the peeling of the wires 73 from the die pad 11.

### Second Modification

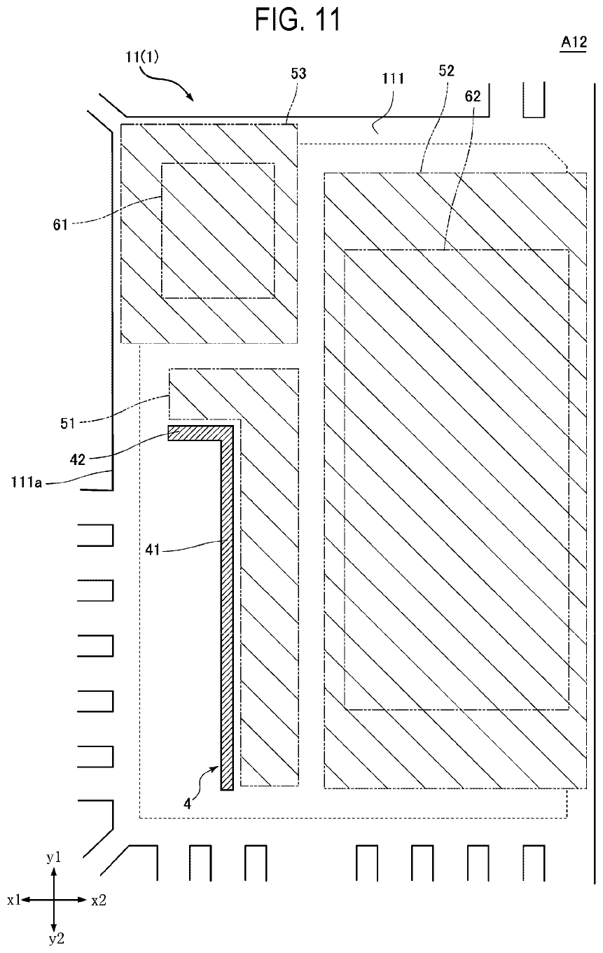

FIG. 11 is a view for explaining a semiconductor device A12 according to a second modification of the first embodiment. FIG. 11 is a plan view showing the die pad 11 of the semiconductor device A12, and corresponds to FIG. 9. The semiconductor device A12 is different from the semiconductor device A10 in the configuration of the openings 4.

The openings 4 of the semiconductor device A12 according to this modification do not include the openings 43 to 45. Also in this modification, since the openings 4 include the openings 41 and 42, the peeling is hindered from progressing to the first region 51 and the second region 52, so that the peeling of the wires 73 and the semiconductor element 61 from the die pad 11 is suppressed.

### Third Modification

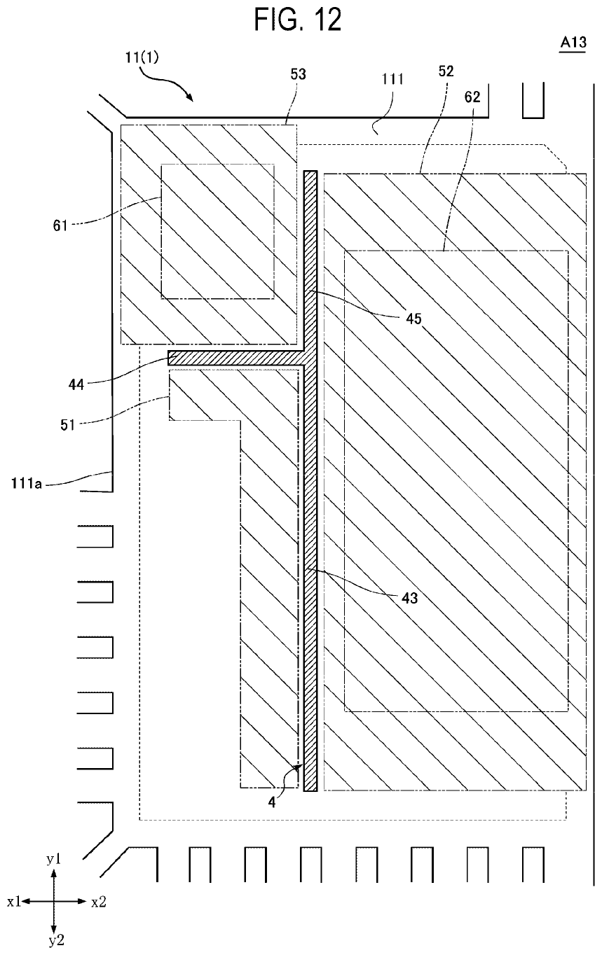

FIG. 12 is a view for explaining a semiconductor device A13 according to a third modification of the first embodiment. FIG. 12 is a plan view showing the die pad 11 of the semiconductor device A13, and corresponds to FIG. 9. The semiconductor device A13 is different from the semiconductor device A10 in the configuration of the openings 4.

The openings 4 of the semiconductor device A13 according to this modification do not include the openings 41 and 42. Also in this modification, since the openings 4 include the openings 43 and 44, it is possible to suppress the outflow of the molten bonding member 65 to the first region 51, and it is also possible to contribute to suppressing the peeling of the wires 73 from the die pad 11. In addition, since the openings 4 include the opening 45, the concentration of stress at the connection point between the opening 43 and the opening 44 is suppressed, and the bonding between the sealing resin 8 and the die pad 11 is strengthened. In addition, since the main surface 111 of the die pad 11 is partitioned into the first region 51, the second region 52, and the third region 53 by the openings 43 to 45, the positions for mounting the semiconductor elements 61 and 62 become clear.

As can be understood from the first to third modifications, the openings 4 need not include all of the openings 41 to 45. The openings 4 may include only a necessary part of the openings 41 to 45.

### Fourth Modification

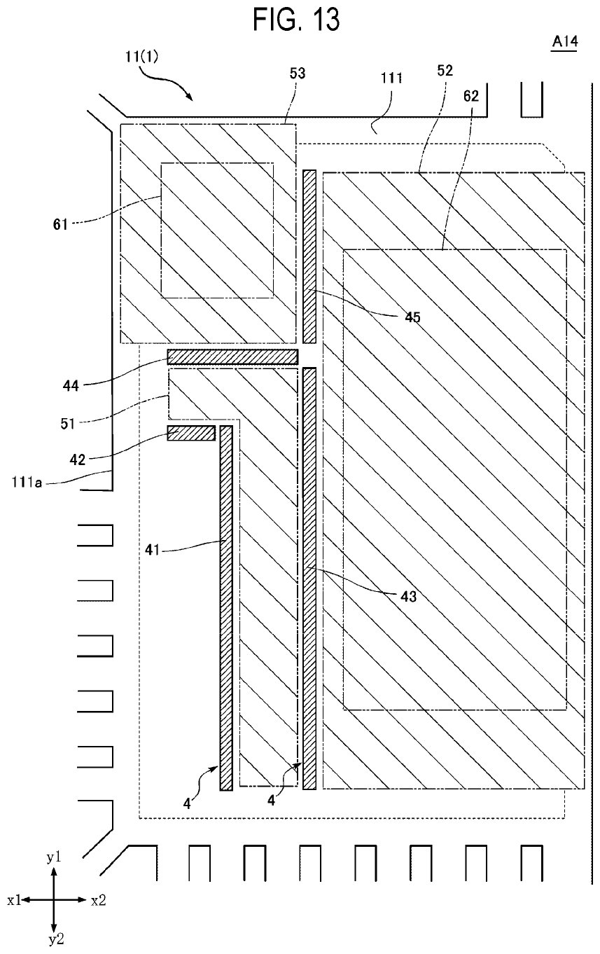

FIG. 13 is a view for explaining a semiconductor device A14 according to a fourth modification of the first embodiment. FIG. 13 is a plan view showing the die pad 11 of the semiconductor device A14, and corresponds to FIG. 9. The semiconductor device A14 is different from the semiconductor device A10 in the configuration of the openings 4.

In the openings 4 of the semiconductor device A14 according to this modification, the openings 41 and 42 are not connected, but are spaced apart from each other. In addition, the openings 43, 44, and 45 are not connected, but are spaced apart from one another. Even when the openings 41 to 45 are not connected to one another but are spaced apart from each other, each of them can hinder the progress of peeling and can also hinder the flow of the molten bonding member 65. In addition, since there is a risk that the peeling may progress via the spaced portions or the molten bonding member 65 may flow out from the spaced portions, distances between the spaced portions may be small, and in some embodiments, the spaced portions may be connected.

### Fifth Modification

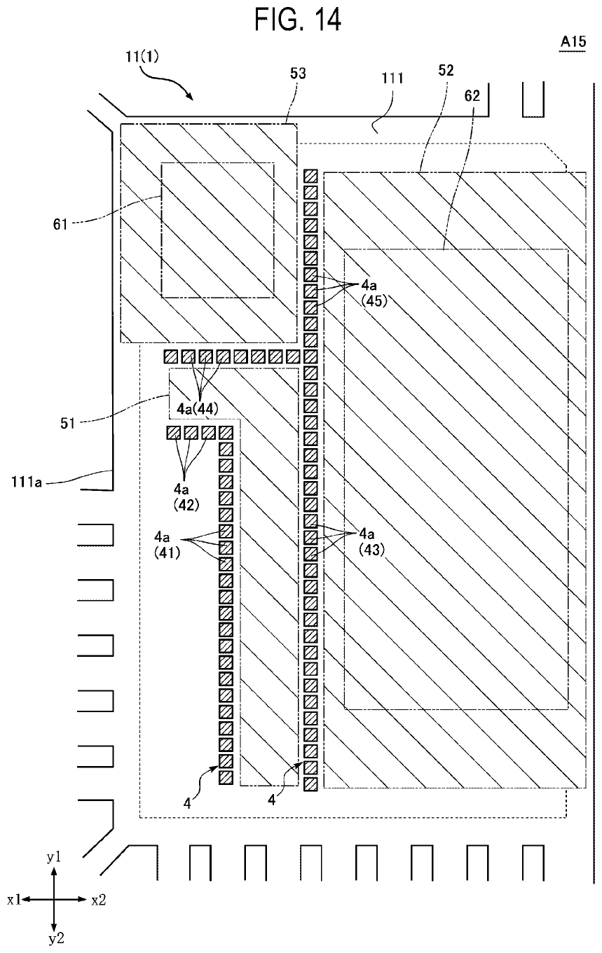

FIG. 14 is a view for explaining a semiconductor device A15 according to a fifth modification of the first embodiment. FIG. 14 is a plan view showing the die pad 11 of the semiconductor device A15, and corresponds to FIG. 9. The semiconductor device A15 is different from the semiconductor device A10 in the configuration of the openings 4.

The openings 4 of the semiconductor device A15 according to this modification are composed of a plurality of portions 4a arranged in the first direction x or the second direction y, instead of having the shape in which each of the openings 41 to 45 extends in the first direction x or the second direction y. Each portion 4a has, for example, a rectangular shape when viewed in the thickness direction z, and is a recess recessed from the main surface 111 toward the second side z2 in the thickness direction z. The shape and size of each portion 4a viewed in the thickness direction z are not limited. Also in this modification, the openings 41 to 45 have the same function as the openings 41 to 45 of the semiconductor device A10.

### Sixth Modification

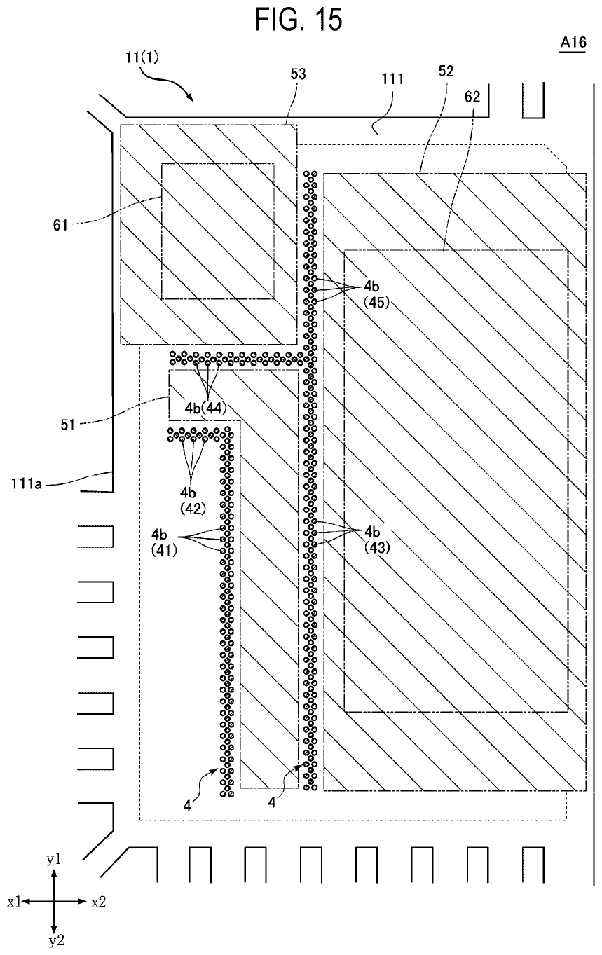

FIG. 15 is a view for explaining a semiconductor device A16 according to a sixth modification of the first embodiment. FIG. 15 is a plan view showing the die pad 11 of the semiconductor device A16, and corresponds to FIG. 9. The semiconductor device A16 is different from the semiconductor device A10 in the configuration of the openings 4.

The openings 4 of the semiconductor device A16 according to this modification are an aggregate of a plurality of portions 4b, instead of having the shape in which each of the openings 41 to 45 extends in the first direction x or the second direction y. Each portion 4b has, for example, a circular shape when viewed in the thickness direction z, and is a recess recessed from the main surface 111 toward the second side z2 in the thickness direction z. The shape and size of each portion 4a viewed in the thickness direction z are not limited. Also in this modification, the openings 41 to 45 have the same function as the openings 41 to 45 of the semiconductor device A10.

### Seventh Modification

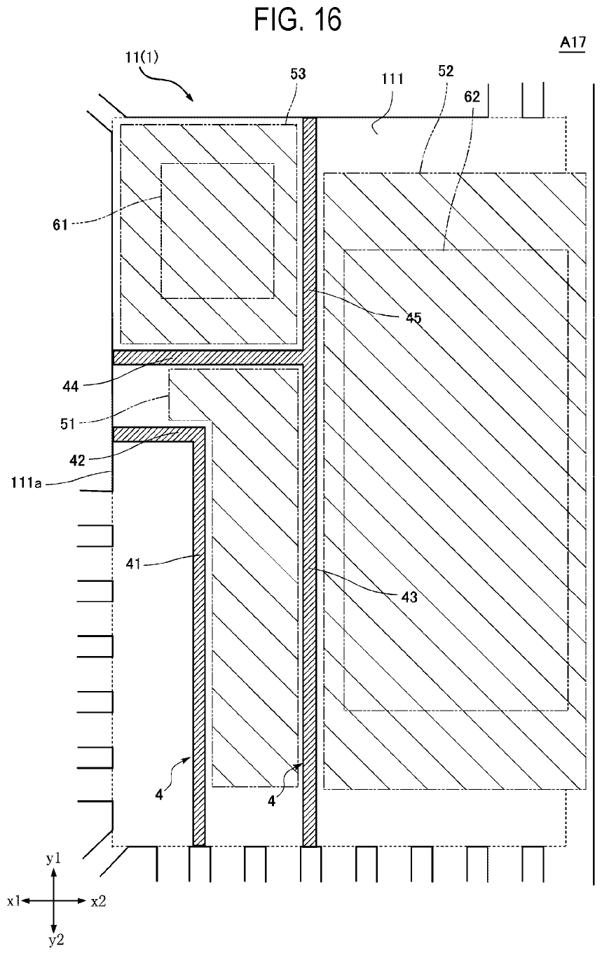

FIG. 16 is a view for explaining a semiconductor device A17 according to a seventh modification of the first embodiment. FIG. 16 is a plan view showing the die pad 11 of the semiconductor device A17, and corresponds to FIG. 9. The semiconductor device A17 is different from the semiconductor device A10 in the configuration of the openings 4.

In the semiconductor device A17 according to this modification, the end of the opening 41 on the second side y2 in the second direction y reaches the outer edge of the main surface 111. Similarly, the end of the opening 43 on the second side y2 in the second direction y, the end of the opening 42 on the first side x1 in the first direction x, the end of the opening 44 on the first side x1 in the first direction x, and the end of the opening 45 on the first side y1 in the second direction y also reach the outer edge of the main surface 111. Also in this modification, the openings 41 to 45 have the same function as the openings 41 to 45 of the semiconductor device A10.

### Eighth Modification

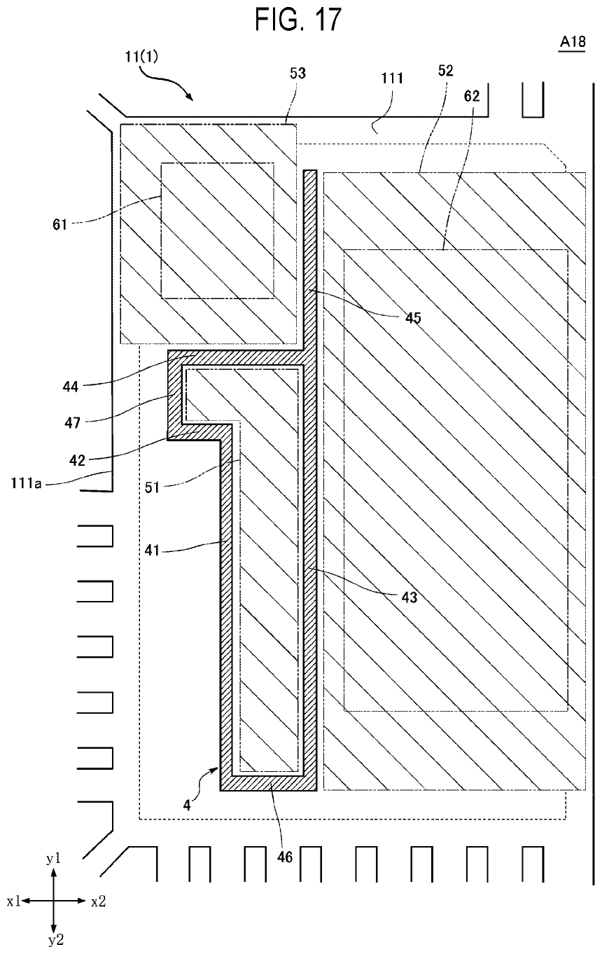

FIG. 17 is a view for explaining a semiconductor device A18 according to an eighth modification of the first embodiment. FIG. 17 is a plan view showing the die pad 11 of the semiconductor device A18, and corresponds to FIG. 9. The semiconductor device A18 is different from the semiconductor device A10 in the configuration of the openings 4.

The openings 4 of the semiconductor device A18 according to this modification further include an opening 46 and an opening 47. The opening 46 is connected to the end of the opening 41 on the second side y2 in the second direction y and to the end of the opening 43 on the second side y2 in the second direction y, and extends in the first direction x. The opening 47 is connected to the end of the opening 42 on the first side x1 in the first direction x and to the end of the opening 44 on the first side x1 in the first direction x, and extends in the second direction y. The opening 46 hinders the peeling from progressing to the first side y1 in the second direction y and to the first region 51. In addition, the opening 47 hinders the peeling from progressing to the second side x2 in the first direction x and to the first region 51. Therefore, the semiconductor device A18 can further suppress the peeling of the wires 73 from the die pad 11.

### Ninth Modification

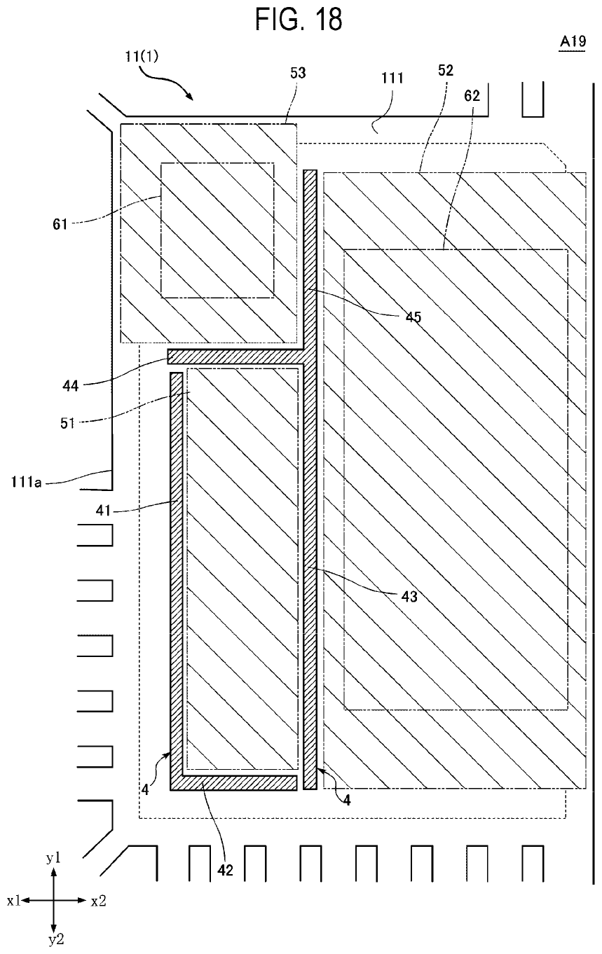

FIG. 18 is a view for explaining a semiconductor device A19 according to a ninth modification of the first embodiment. FIG. 18 is a plan view showing the die pad 11 of the semiconductor device A19, and corresponds to FIG. 9. The semiconductor device A19 is different from the semiconductor device A10 in the configuration of the openings 4.

The opening 41 of the semiconductor device A19 according to this modification is arranged at the same position in the first direction x as the end of the opening 44 on the first side x1. In addition, the opening 41 may be connected to the opening 44. The opening 42 is connected to the end of the opening 41 on the second side y2 in the second direction y and extends to the second side x2 in the first direction x. In addition, the opening 42 may be connected to the opening 43. Also in this modification, the opening 41 has the same function as the opening 41 of the semiconductor device A10. In addition, the opening 42 hinders the peeling from progressing to the first side y1 in the second direction y and to the first region 51. Therefore, the semiconductor device A19 can further suppress the peeling of the wires 73 from the die pad 11.

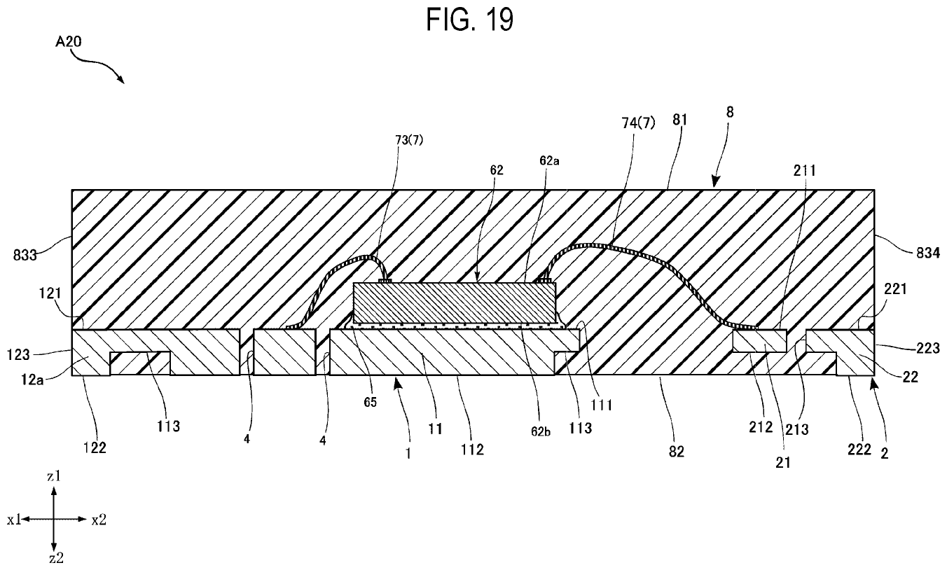

FIGS. 19 to 23 show other embodiments of the present disclosure. In these figures, the same or similar elements as in the above embodiment are denoted by the same reference numerals as in the above embodiment.

### Second Embodiment

FIG. 19 is a view for explaining a semiconductor device A20 according to a second embodiment of the present disclosure. FIG. 19 is a cross-sectional view showing the semiconductor device A20, and corresponds to FIG. 5. The semiconductor device A20 of the present embodiment is different from the semiconductor device A10 of the first embodiment in that the openings 4 penetrate the die pad 11 in the thickness direction z. The configuration and operation of other portions of the present embodiment are the same as those of the first embodiment. In addition, various parts of the above-described first embodiment and modifications may be combined arbitrarily. In the present embodiment, all of the openings 41 to 45 of the openings 4 penetrate the die pad 11 in the thickness direction z.

Also in the present embodiment, since the openings 41 to 45 respectively hinder the progress of peeling and hinder the outflow of the molten bonding member 65, they perform the same function as the openings 41 to 45 of the semiconductor device A10. As a result, the semiconductor device A20 can suppress the wire 73 from being peeled from the die pad 11 and suppress the bonding member 65 from hindering the bonding of the wire 73. In addition, the semiconductor device A20 has the same effects as the semiconductor device A10 by adopting a configuration in common with the semiconductor device A10.

### Third Embodiment

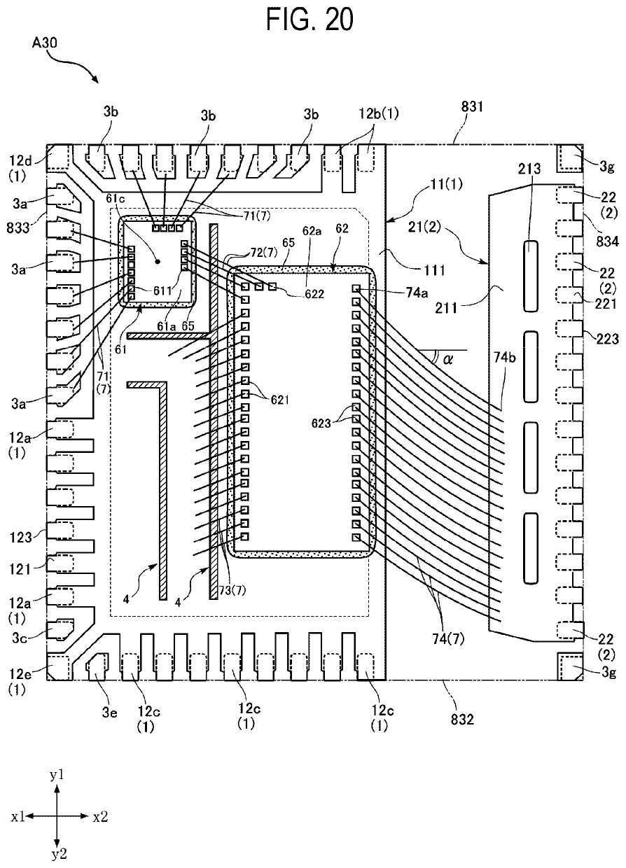

FIG. 20 is a view for explaining a semiconductor device A30 according to a third embodiment of the present disclosure. FIG. 20 is a plan view showing the semiconductor device A30, and corresponds to FIG. 2. In FIG. 20, for the sake of convenience of understanding, the sealing resin 8 is transparent and the outer shape of the sealing resin 8 is shown by an imaginary line (two-dot chain line). The semiconductor device A30 of the present embodiment is different from the semiconductor device A10 of the first embodiment in the shape of the lead 2. The configuration and operation of other portions of the present embodiment are the same as those of the first embodiment. In addition, various parts of the above-described first and second embodiments and modifications may be combined arbitrarily.

The lead 2 according to the present embodiment has a larger dimension in the second direction y than the lead 2 according to the first embodiment, and includes fourteen terminals 22. The semiconductor device A30 does not have the lead 3f, and the pad 21 extends in the second direction y to a position where the lead 3f is arranged in the first embodiment. That is, the lead 2 according to the present embodiment is formed by connecting the lead 3f to the lead 2 in the first embodiment. In the present embodiment, since the dimension of the pad 21 in the second direction y is increased, the plurality of wires 74 is bonded to the second side y2 in the second direction y of the main surface 211 of the pad 21.

Also in the present embodiment, since all the wires 74 are inclined with respect to the first direction x when viewed in the thickness direction z, the wire sweep of each wire 74 is suppressed, and in the semiconductor device A30, contact between the wires 74 due to the wire sweep is suppressed. In addition, also in the present embodiment, since all the wires 74 have the same inclination direction with respect to the first direction x, the wire sweep in the wires 74 is suppressed, and in the semiconductor device A30, contact between the wires 74 due to the wire sweep is suppressed. In addition, according to the present embodiment, since the bonding portion 74b of each wire 74 is bonded to the second side y2 in the second direction y of the main surface 211 of the pad 21, the inclination angle α of each wire 74 with respect to the first direction x becomes larger than that in the first embodiment. As a result, since the component that affects the wire sweep is reduced, the wire sweep is further suppressed in the semiconductor device A30. In addition, the semiconductor device A30 has the same effects as the semiconductor device A10 by adopting a configuration in common with the semiconductor device A10.

### First Modification

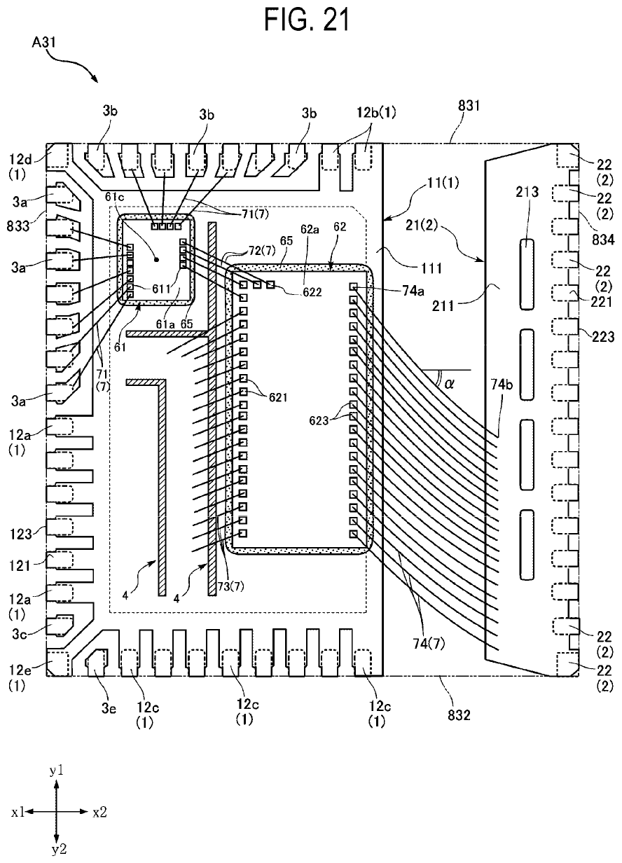

FIG. 21 is a view for explaining a semiconductor device A31 according to a first modification of the third embodiment. FIG. 21 is a plan view showing the semiconductor device A31, and corresponds to FIG. 2. In FIG. 21, for the sake of convenience of understanding, the sealing resin 8 is transparent and the outer shape of the sealing resin 8 is shown by an imaginary line (two-dot chain line). In FIG. 21, the same or similar elements as in the third embodiment are denoted by the same reference numerals as in the third embodiment, and duplicate explanation thereof will be omitted. The semiconductor device A31 is different from the semiconductor device A30 in the shape of the lead 2.

The lead 2 of the semiconductor device A31 according to this modification has a larger dimension in the second direction y than the lead 2 according to the third embodiment, and includes sixteen terminals 22. The semiconductor device A31 does not have the lead 3g, and the pad 21 extends in the second direction y to a position where the lead 3g is arranged in the third embodiment. That is, the lead 2 according to this modification is formed by connecting the lead 3g to the lead 2 in the third embodiment. In this modification, since the dimension of the pad 21 in the second direction y is further increased, the plurality of wires 74 is bonded to the second side y2 in the second direction y of the main surface 211 of the pad 21. According to this modification, the inclination angle α of each wire 74 with respect to the first direction x becomes larger than that in the third embodiment. As a result, since the component that affects the wire sweep is reduced, the wire sweep is further suppressed in the semiconductor device A31.

### Fourth Embodiment

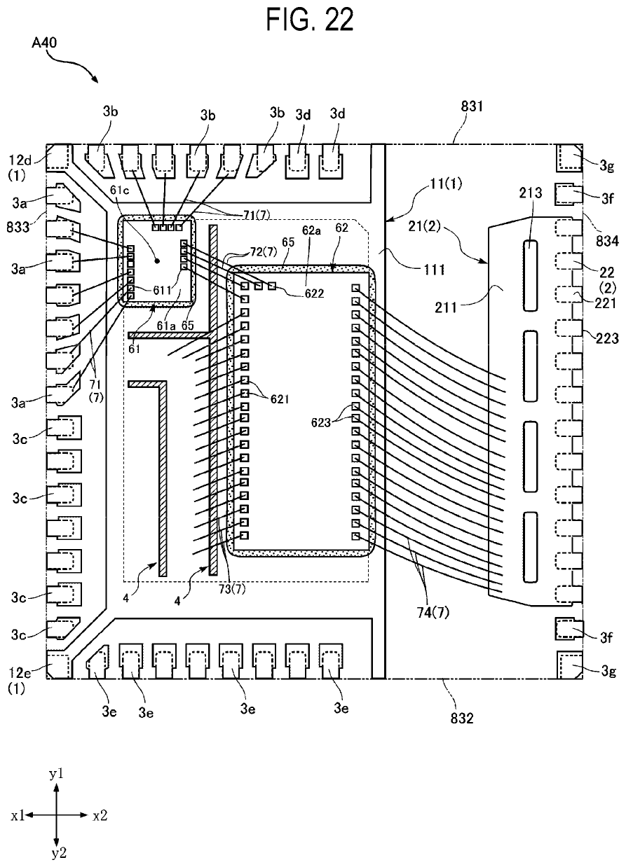

FIG. 22 is a view for explaining a semiconductor device A40 according to a fourth embodiment of the present disclosure. FIG. 22 is a plan view showing the semiconductor device A40, and corresponds to FIG. 2. In FIG. 22, for the sake of convenience of understanding, the sealing resin 8 is transparent and the outer shape of the sealing resin 8 is indicated by an imaginary line (two-dot chain line). The semiconductor device A40 of the present embodiment is different from the semiconductor device A10 of the first embodiment in the configuration of the lead 1. The configuration and operation of other portions of the present embodiment are the same as those of the first embodiment. Further, various parts of the above-described first to third embodiments and modifications may be combined arbitrarily. The lead 1 according to the present embodiment does not include the terminal 12a, the terminal 12b, and the terminal 12c. The semiconductor device A40 has a lead 3c instead of the terminal 12a, a lead 3d instead of the terminal 12b, and a lead 3e instead of the terminal 12c. The leads 3c, 3d, and 3e have the same configuration as the other leads 3 and are spaced apart from the die pad 11. Each lead 3c is arranged on the second side y2 with respect to the plurality of leads 3a in the second direction y. In each lead 3c, the pad 31 extends to the second side x2 in the first direction x. Each lead 3d is arranged on the second side x2 with respect to the plurality of leads 3b in the first direction x. In each lead 3d, the pad 31 extends to the second side y2 in the second direction y. Each lead 3e is arranged on the second side x2 with respect to the terminal 12e in the first direction x. In each lead 3e, the pad 31 extends to the first side y1 in the second direction y. The leads 3c, 3d, and 3e are so-called dummy leads.

Also in the present embodiment, the semiconductor device A40 has the same effects as the semiconductor device A10 by adopting a configuration in common with the semiconductor device A10.

### Fifth Embodiment

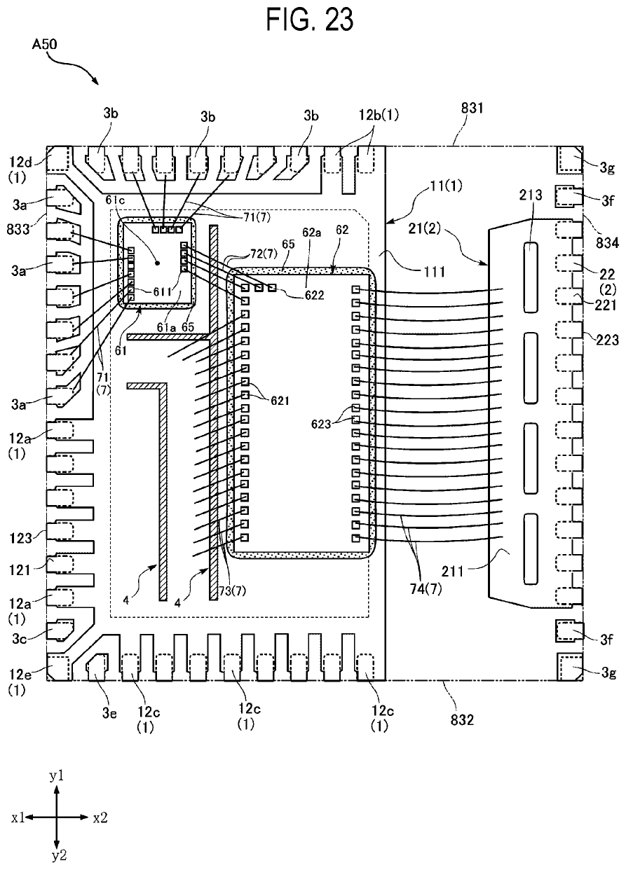

FIG. 23 is a view for explaining a semiconductor device A50 according to a fifth embodiment of the present disclosure. FIG. 23 is a plan view showing the semiconductor device A50, and corresponds to FIG. 2. In FIG. 23, for the sake of convenience of understanding, the sealing resin 8 is transparent and the outer shape of the sealing resin 8 is indicated by an imaginary line (two-dot chain line). The semiconductor device A50 of the present embodiment is different from the semiconductor device A10 of the first embodiment in that all of the plurality of wires 74 are substantially parallel to the first direction x when viewed in the thickness direction z. The configuration and operation of other portions of the present embodiment are the same as those of the first embodiment. Further, various parts of the above-described first to fourth embodiments and modifications may be combined arbitrarily.

In the present embodiment, in each wire 74, the bonding portion 74a bonded to the semiconductor element 62 and the bonding portion 74b bonded to the lead 2 are at the same position in the second direction y. That is, all of the plurality of wires 74 are substantially parallel to the first direction x when viewed in the thickness direction z.

According to the present embodiment, since each wire 74 is substantially parallel to the first direction x when viewed in the thickness direction z, the wire length can be shortened as compared with a case where the wire 74 is inclined with respect to the first direction x. As a result, the semiconductor device A50 can reduce a resistance value of the wire 74. In addition, the semiconductor device A50 has the same effects as the semiconductor device A10 by adopting a configuration in common with the semiconductor device A10.

In the first to fifth embodiments, the case where the semiconductor element 61 is located on the first side x1 in the first direction x and the first side y1 in the second direction y with respect to the semiconductor element 62 and is arranged at a position shifted from the center of the main surface 111 of the die pad 11 to the first side x1 in the first direction x and the first side y1 in the second direction y has been described, but the present disclosure is not limited thereto. For example, the semiconductor element 61 may be aligned with the semiconductor element 62 in the first direction x and may be arranged on the first side x1 with respect to the semiconductor element 62. In this case, the semiconductor element 61 is shifted from the center of the main surface 111 of the die pad 11 to the first side x1 in the first direction x and is arranged at the center of the main surface 111 in the second direction y. In this case, the pad 31 of the lead 3b is formed to extend toward the element center 61c which is the center of the semiconductor element 61 when viewed in the thickness direction z, and the pad 31 of the lead 3a is formed to extend toward the center of the main surface 111 of the die pad 11 when viewed in the thickness direction z. In addition, the semiconductor element 61 may be aligned with the semiconductor element 62 in the second direction y and may be arranged on the first side y1 with respect to the semiconductor element 62. In this case, the semiconductor element 61 is shifted from the center of the main surface 111 of the die pad 11 to the first side y1 in the second direction y and is arranged at the center of the main surface 111 in the first direction x. In this case, the pad 31 of the lead 3a is formed to extend toward the element center 61c which is the center of the semiconductor element 61 when viewed in the thickness direction z, and the pad 31 of the lead 3b is formed to extend toward the center of the main surface 111 of the die pad 11 when viewed in the thickness direction z.

The semiconductor device according to the present disclosure is not limited to the above-described embodiments. The specific configuration of respective components of the semiconductor device according to the present disclosure can be freely changed in design in various ways.

[Supplementary Note 1]

A semiconductor device (A10) including:
a first lead (1) having a die pad (11);
a second lead (2) arranged to be spaced apart from the first lead;
a first semiconductor element (62) mounted on the die pad; and
a plurality of wires (74) electrically connected to the first semiconductor element and the second lead,
wherein the die pad and the second lead are arranged side by side in a first direction (x) perpendicular to a thickness direction (z), and
wherein all of the plurality of wires are inclined with respect to the first direction when viewed in the thickness direction.

[Supplementary Note 2]

The semiconductor device of Supplementary Note 1, wherein each of the plurality of wires includes a first bonding portion (74a) bonded to the first semiconductor element and a second bonding portion (74b) bonded to the second lead, and wherein the first bonding portion is located on a first side (y1) in a second direction (y), which is perpendicular to the thickness direction and the first direction, from the second bonding portion.

[Supplementary Note 3, FIG. 7]

The semiconductor device of Supplementary Note 2, wherein the second lead has a second lead main surface (211) facing a first side (z1) in the thickness direction,
wherein the second lead main surface includes a bonding region (211a) to which the plurality of wires is bonded and a non-bonding region (211b) to which the wires are not bonded, and
wherein the non-bonding region is arranged on the first side in the second direction of the bonding region.

[Supplementary Note 4, FIG. 7]

The semiconductor device of Supplementary Note 3, wherein a first dimension (L1) of the bonding region in the second direction is 40% or more and 60% or less of a second dimension (L2) of the second lead in the second direction.

[Supplementary Note 5]

The semiconductor device of any one of Supplementary Notes 1 to 4, wherein dummy leads (3f, 3g) are respectively arranged on both sides of the second lead in the second direction (y), which is perpendicular to the thickness direction and the first direction.

[Supplementary Note 6]

The semiconductor device of any one of Supplementary Notes 1 to 5, wherein each of the plurality of wires is curved in the second direction, which is perpendicular to the thickness direction and the first direction.

[Supplementary Note 7]

The semiconductor device of any one of Supplementary Notes 1 to 6, wherein the second lead has a through-hole (213) penetrating in the thickness direction.

[Supplementary Note 8]

The semiconductor device of any one of Supplementary Notes 1 to 7, wherein the first semiconductor element is a switching element.

[Supplementary Note 9]

The semiconductor device of Supplementary Note 8, wherein the first semiconductor element contains GaN.

[Supplementary Note 10]

The semiconductor device of any one of Supplementary Notes 1 to 9, further including a second semiconductor element (61) mounted on the die pad,
wherein the die pad has a die pad main surface (111), which faces a first side in the thickness direction and on which the first semiconductor element and the second semiconductor element are mounted,
wherein the second semiconductor element is arranged on a first side (x1) in the first direction (x), which is opposite to the second lead with respect to the first semiconductor element in the first direction, and
wherein the second semiconductor element is a drive element that drives the first semiconductor element.

[Supplementary Note 11, FIG. 9]

The semiconductor device of Supplementary Note 10, further including a second wire (73) electrically connected to the first semiconductor element and the die pad main surface,
wherein the die pad main surface includes a first region (51), which is located on the first side in the first direction of the first semiconductor element and to which the second wire is bonded, a second region (52) on which the first semiconductor element is mounted, and a third region (53) on which the second semiconductor element is mounted, and
wherein the die pad includes an opening (4) having an open end on the die pad main surface and partitioning the first region, the second region, and the third region.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first lead having a die pad;
a second lead arranged to be spaced apart from the first lead;
a first semiconductor element mounted on the die pad; and
a plurality of wires electrically connected to the first semiconductor element and the second lead,
wherein the die pad and the second lead are arranged side by side in a first direction perpendicular to a thickness direction, and
wherein all of the plurality of wires are inclined with respect to the first direction when viewed in the thickness direction.

2. The semiconductor device of claim 1, wherein each of the plurality of wires includes a first bonding portion bonded to the first semiconductor element and a second bonding portion bonded to the second lead, and
wherein the first bonding portion is located on a first side in a second direction, which is perpendicular to the thickness direction and the first direction, from the second bonding portion.

3. The semiconductor device of claim 2, wherein the second lead has a second lead main surface facing a first side in the thickness direction,
wherein the second lead main surface includes a bonding region to which the plurality of wires is bonded and a non-bonding region to which the wires are not bonded, and
wherein the non-bonding region is arranged on the first side in the second direction of the bonding region.

4. The semiconductor device of claim 3, wherein a first dimension of the bonding region in the second direction is 40% or more and 60% or less of a second dimension of the second lead in the second direction.

5. The semiconductor device of claim 1, wherein dummy leads are respectively arranged on both sides of the second lead in a second direction, which is perpendicular to the thickness direction and the first direction.

6. The semiconductor device of claim 1, wherein each of the plurality of wires is curved in a second direction, which is perpendicular to the thickness direction and the first direction.

7. The semiconductor device of claim 1, wherein the second lead has a through-hole penetrating in the thickness direction.

8. The semiconductor device of claim 1, wherein the first semiconductor element is a switching element.

9. The semiconductor device of claim 8, wherein the first semiconductor element contains GaN.

10. The semiconductor device of claim 1, further comprising a second semiconductor element mounted on the die pad,
wherein the die pad has a die pad main surface, which faces a first side in the thickness direction and on which the first semiconductor element and the second semiconductor element are mounted,
wherein the second semiconductor element is arranged on a first side in the first direction, which is opposite to the second lead with respect to the first semiconductor element in the first direction, and
wherein the second semiconductor element is a drive element that drives the first semiconductor element.

11. The semiconductor device of claim 10, further comprising a second wire electrically connected to the first semiconductor element and the die pad main surface,
wherein the die pad main surface includes a first region, which is located on the first side in the first direction of the first semiconductor element and to which the second wire is bonded, a second region on which the first semiconductor element is mounted, and a third region on which the second semiconductor element is mounted, and
wherein the die pad includes an opening having an open end on the die pad main surface and partitioning the first region, the second region, and the third region.
